(19) United States
(12) Patent Application Publication
(10) Pub. No.: US 2026/0371694 A1
(43) Pub. Date: Nov. 19, 2026

(54) CONTACT STRUCTURES IN SEMICONDUCTOR DEVICES

(71) Applicant: Taiwan Semiconductor Manufacturing Company, Ltd., Hsinchu (TW)

(72) Inventors: Shuen-Shin LIANG, Hsinchu (TW); Lo-Heng CHANG, Hsinchu (RW); Pinyen LIN, Hsinchu (TW); Shih-Chuan CHIU, Hsinchu (TW); Hsu-Kai CHANG, Hsinchu (TW); Huan-Chieh SU, Changhua (TW); Keng-Chu LIN, Ping-Tung (TW); Ko-Feng CHEN, Hsinchu (TW); Sung-Li WANG, Hsinchu (TW)

(73) Assignee: Taiwan Semiconductor Manufacturing Company, Ltd., Hsinchu (TW)

(21) Appl. No.: 19/736,051

(22) Filed: Jul. 9, 2026

Related U.S. Application Data
(62) Division of application No. 17/681,346, filed on Feb. 25, 2022.
(60) Provisional application No. 63/219,951, filed on Jul. 9, 2021.

(51) Int. Cl. H10D 64/62; H10D 30/01; H10D 30/67; H10D 62/10; H10D 64/01; H10D 84/01; H10D 84/03; H10D 84/85; H10P 14/20

(52) U.S. Cl. CPC H10D 64/62; H10D 30/031; H10D 30/6729; H10D 30/6735; H10D 30/6757; H10D 62/118; H10D 64/0112; H10D 84/0167; H10D 84/017; H10D 84/0186; H10D 84/038; H10D 84/85; H10P 14/3452

(57) ABSTRACT

A semiconductor device with different configurations of contact structures and a method of fabricating the same are disclosed. The method includes forming first and second fin structures on a substrate, forming n-and p-type source/drain (S/D) regions on the first and second fin structures, respectively, forming first and second contact openings on the n- and p-type S/D regions, respectively, forming a carbon-based layer in the first and second contact openings, performing a remote plasma treatment with radicals on the carbon-based layer to form a remote plasma treated layer, selectively removing a portion of the remote plasma treated layer, forming a p-type work function metal (pWFM) silicide layer on the p-type S/D region, and forming an n-type work function metal (nWFM) silicide layer on the pWFM silicide layer and on the n-type S/D region.

### CROSS-REFERENCE TO RELATED APPLICATIONS

This application is a divisional of U.S. patent application Ser. No. 17/681,346, titled “Contact Structures in Semiconductor Devices,” filed Feb. 25, 2022, which claims the benefit of U.S. Provisional Patent Application No. 63/219,951, titled “Sidewall Profile Control of Spacers in Semiconductor Devices,” filed Jul. 9, 2021, each of which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1 illustrates an isometric view of a semiconductor device, in accordance with some embodiments.

FIGS. 2A-2F illustrate cross-sectional views of a semiconductor device with different contact structures, in accordance with some embodiments.

FIG. 3 is a flow diagram of a method for fabricating a semiconductor device with different contact structures, in accordance with some embodiments.

FIGS. 4A-16A, 4B-16B, 4C-16C, and 4D-16D illustrate cross-sectional views of a semiconductor device with different contact structures at various stages of its fabrication process, in accordance with some embodiments.

FIG. 9E illustrates a chemical structure of a carbide material of a barrier layer of a contact structure, in accordance with some embodiments.

FIGS. 9F-G illustrate chemical compositions of a barrier layer of a contact structure at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

The fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

The present disclosure provides example semiconductor devices with FETs (e.g., finFETs) having source/drain (S/D) contact structures different from each other and provides example methods of forming such FETs on the same substrate with improved sidewall profiles of the S/D contact structures. The example method forms arrays of n-and p-type S/D regions on fin structures of n-type FETs (NFETs) and p-type FETs (PFETs), respectively, of the semiconductor device. In some embodiments, S/D contact structures on n-type S/D regions have silicide layers different from silicide layers of S/D contact structures on p-type S/D regions.

The contact resistances between the S/D regions and the S/D contact structures are directly proportional to the Schottky barrier heights (SBHs) between the materials of the S/D regions and the silicide layers of the S/D contact structures. For n-type S/D regions, reducing the difference between the work function value of the silicide layers and the conduction band energy of the n-type material of the S/D regions can reduce the SBH between the n-type S/D regions and the S/D contact structures. In contrast, for p-type S/D regions, reducing the difference between the work function value of the silicide layers and the valence band energy of the p-type material of the S/D regions can reduce the SBH between the p-type S/D regions and the S/D contact structures. In some embodiments, since the S/D regions of NFETs and PFETs are formed with respective n-type and p-type materials, the S/D contact structures of NFETs and PFETs are formed with silicide layers different from each other to reduce the contact resistances between the S/D contact structures and the different materials of the S/D regions.

In some embodiments, the NFET S/D contact structures are formed with n-type work function metal (nWFM) silicide layers (e.g., titanium silicide) that have a work function value closer to a conduction band energy than a valence band energy of the n-type S/D regions. In contrast, the PFET S/D contact structures are formed with p-type WFM (pWFM) silicide layers (e.g., nickel silicide or cobalt silicide) that have a work function value closer to a valence band energy than a conduction band energy of the p-type S/D regions. The nWFM silicide layers can be formed from a silicidation reaction between the n-type S/D regions and an nWFM layer disposed on the n-type S/D regions. The pWFM silicide layers can be formed from a silicidation reaction between the p-type S/D regions and a pWFM layer disposed on the p-type S/D regions.

The formation of different silicide layers in NFET and PFET, instead of the formation of a single silicide layer for both NFET and PFET, increases the number of etching processes (e.g., native oxide etching processes) in the silicide layer formation process. The increased number of etching processes increases the challenges of preserving the structural and functional integrity of dielectric barrier layers in the S/D contact structures during the etching processes. The dielectric barrier layers along sidewalls of the S/D contact structures protect adjacent FET structures during the formation of S/D contact structures and provide electrical isolation between the S/D contact structures and the adjacent FET structures. Significant loss of the dielectric barrier layer material during the etching processes can damage the adjacent FET structures and/or induce shorting between the S/D contact structures and the adjacent FET structures.

In some embodiments, the dielectric barrier layers can include carbon-based materials (e.g., carbides or oxycarbides) with a carbide-to-oxide etch selectivity ranging from about 40 to about 100 or greater than about 100, a density greater than about 1.7 gm/cm³, and a dielectric constant less than about 5. In some embodiments, the carbon-based barrier layers (also referred to as “carbide barrier layers”) include only silicon-carbon (Si—C) bonds or only a combination of Si—C and silicon-oxygen (Si—O) bonds with a larger number of Si—C bonds than Si—O bonds. The Si—C bonds can provide carbide barrier layers with a greater chemical stability, thermal stability, resistance to etching, resistance to oxygen diffusion, and etch selectivity over oxide compared to nitride barrier layers (e.g., silicon nitride (SiN) barrier layers). Also, compared to nitride barrier layers, carbide barrier layers have a lower dielectric constant, a higher etch selectivity over oxide, a higher density, and a higher breakdown voltage.

The high density and high carbide-to-oxide etch selectivity can prevent or minimize etching of the carbide barrier layers during the native oxide etching in the silicide layer formation process. In some embodiments, during the native oxide etching processes, a total thickness of about 0.1 nm to about 1 nm of the carbide barrier layers can be etched, which is about 5 to about 10 times less than the total thickness of nitride barrier layers etched during the native oxide etching processes. As a result, carbide barrier layers with smaller thicknesses (e.g., about 2 to about 5 times smaller) than nitride barrier layers can be formed to adequately protect adjacent FET structures during the etching processes and provide electrical isolation between the S/D contact structures and the adjacent FET structures. Also, due to lower dielectric constant of carbide barrier layers compared to that of nitride barrier layers, thinner carbide barrier layers can be used compared to nitride barrier layers without increasing the FET parasitic capacitances. Thus, with the use of carbide barrier layers in S/D contact structures, device dimensions and manufacturing cost can be reduced without compromising device performance.

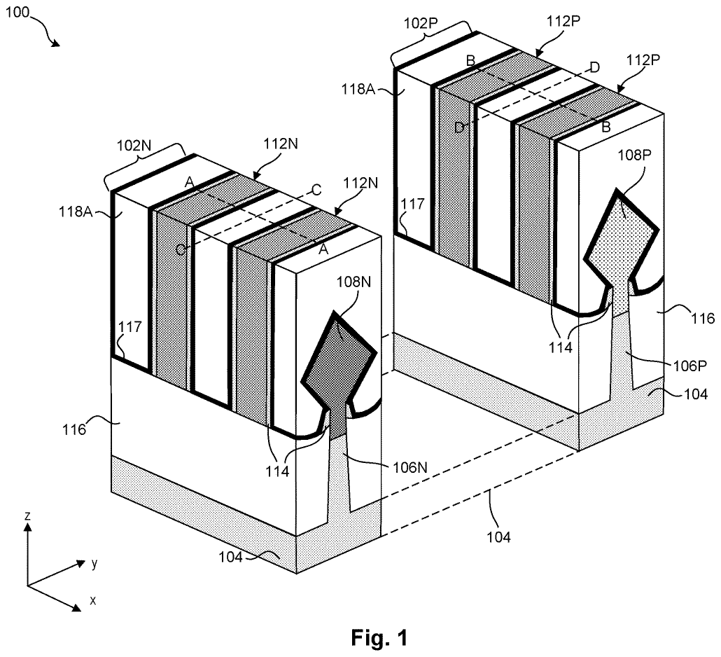

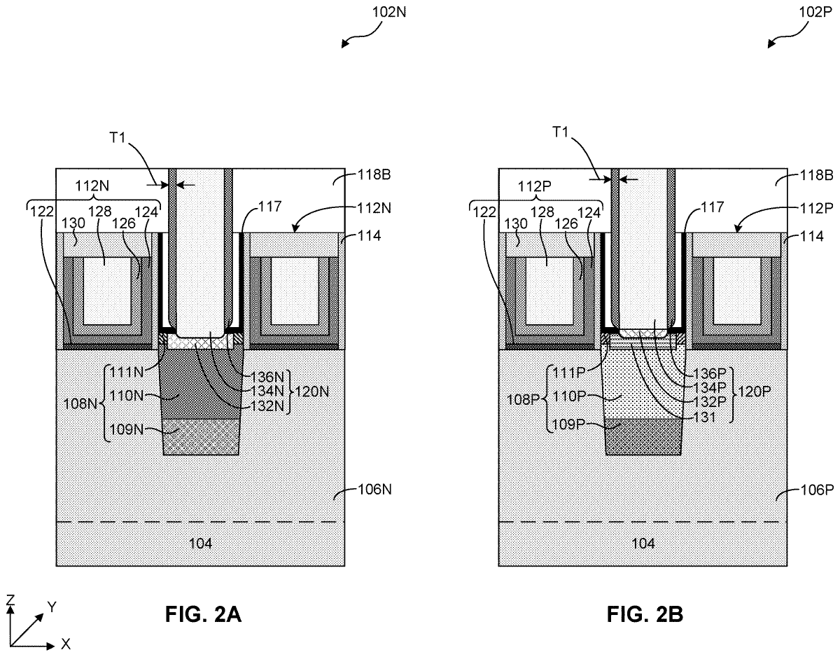

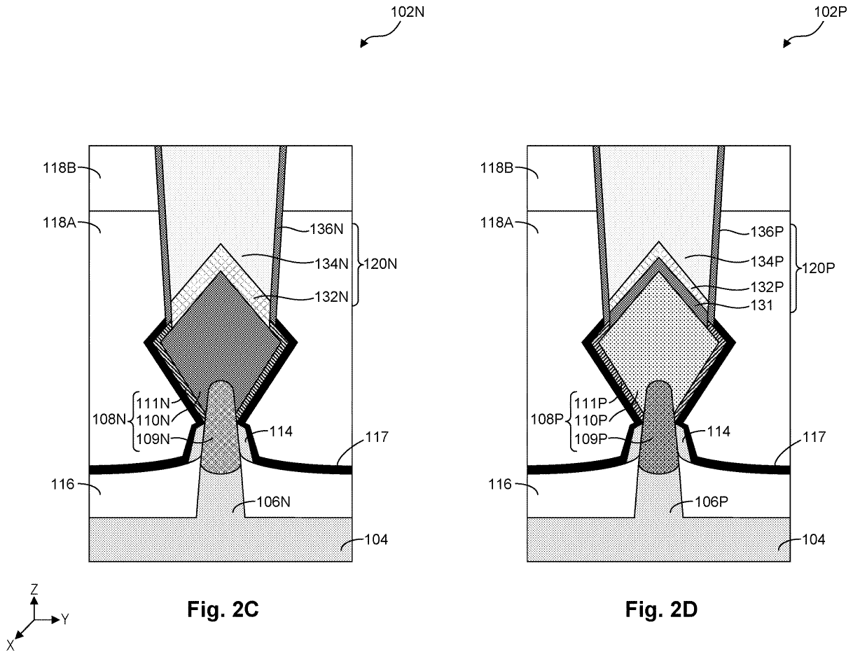

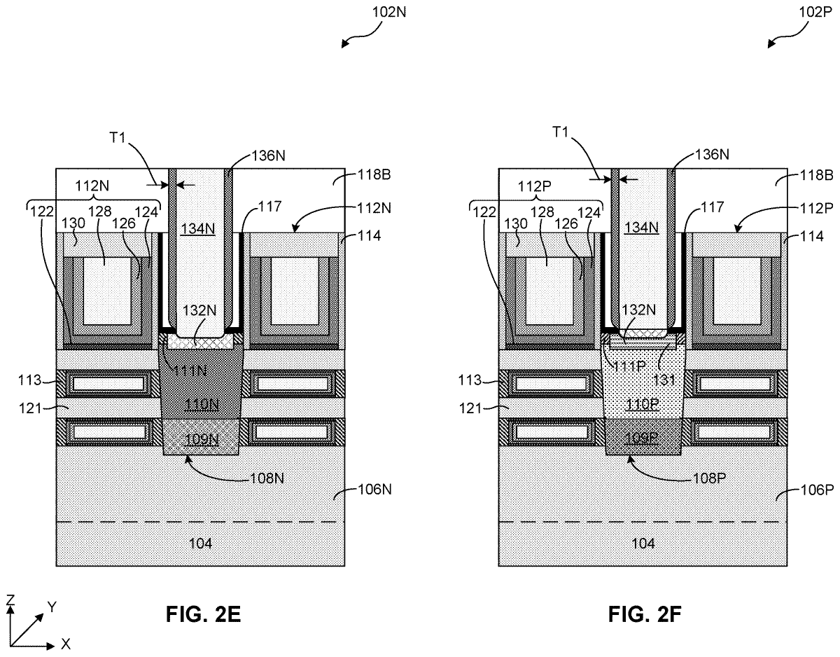

FIG. 1 illustrates an isometric view of a semiconductor device 100 with NFET 102N and PFET 102P, according to some embodiments. FIG. 2A and illustrate cross-sectional views of NFET 102N along respective lines A-A and C-C of FIG. 1. FIGS. 2B and 2D illustrate cross-sectional views of PFET 102P along respective lines B-B and D-D of FIG. 1. FIGS. 2A-2D illustrate cross-sectional views of semiconductor device 100 with additional structures that are not shown in FIG. 1 for simplicity. The discussion of elements of NFET 102N and PFET 102P with the same annotations applies to each other, unless mentioned otherwise.

Referring to FIG. 1, NFET 102N can include an array of gate structures 112N disposed on fin structure 106N, and PFET 102P can include an array of gate structures 112P disposed on fin structure 106P. NFET 102N can further include an array of S/D regions 108N (one of S/D regions 108N visible in FIG. 1) disposed on portions of fin structure 106N that are not covered by gate structures 112N. Similarly, PFET 102P can further include an array of epitaxial S/D regions 108P (one of S/D regions 108P visible in FIG. 1) disposed on portions of fin structure 106P that are not covered by gate structures 112P.

Semiconductor device 100 can further include gate spacers 114, shallow trench isolation (STI) regions 116, etch stop layer (ESL) 117, and interlayer dielectric (ILD) layers 118A-118B (ILD layer 118B not shown in FIG. 1 for simplicity; shown in FIGS. 2A-2D). ILD layer 118A can be disposed on ESL 117. ESL 117 can be configured to protect gate structures 112N and 112P and/or S/D regions 108N and 108P. In some embodiments, gate spacers 114, STI regions 116, ESL 117, and ILD layers 118A-118B can include an insulating material, such as silicon oxide, silicon nitride (SiN), silicon carbon nitride (SiCN), silicon oxycarbon nitride (SiOCN), and silicon germanium oxide.

Semiconductor device 100 can be formed on a substrate 104 with NFET 102N and PFET 102P formed on different regions of substrate 104. There may be other FETs and/or structures (e.g., isolation structures) formed between NFET 102N and PFET 102P on substrate 104. Substrate 104 can be a semiconductor material, such as silicon, germanium (Ge), silicon germanium (SiGe), a silicon-on-insulator (SOI) structure, and a combination thereof. Further, substrate 104 can be doped with p-type dopants (e.g., boron, indium, aluminum, or gallium) or n-type dopants (e.g., phosphorus or arsenic). In some embodiments, fin structures 106N-106P can include a material similar to substrate 104 and extend along an X-axis.

Referring to FIGS. 2A-2D, NFET-PFET 102N-102P can include gate structures 112N-112P, S/D regions 108N-108P, and S/D contact structures 120N-120P disposed on S/D regions 108N-108P. Gate structures 112N-112P can be multi-layered structures. Each of gate structures 112N-112P can include an interfacial oxide (IO) layer 122, a high-k (HK) gate dielectric layer 124 disposed on IO layer 122, a work function metal (WFM) layer 126 disposed on HK gate dielectric layer 124, a gate metal fill layer 128 disposed on WFM layer 126, and a gate capping layer 130 disposed on HK gate dielectric layer 124, WFM layer 126, and gate metal fill layer 128.

IO layers 122 can include silicon oxide (SiO₂), silicon germanium oxide (SiGeOₓ), or germanium oxide (GeOₓ). HK gate dielectric layers 124 can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂). WFM layers 126 of gate structures 112N can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, a combination thereof, or other suitable Al-based materials. WFM layers 126 of gate structures 112P can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, tantalum copper (Ta-Cu), and a combination thereof. Gate metal fill layers 128 can include a suitable conductive material, such as tungsten (W), Ti, silver (Ag), ruthenium (Ru), molybdenum (Mo), copper (Cu), cobalt (Co), Al, iridium (Ir), nickel (Ni), metal alloys, and a combination thereof. In some embodiments, gate structures 112N-112P can be electrically isolated from overlying interconnect structures (not shown) by gate capping layers 130, which can include nitride layers.

Each of S/D regions 108N can include a stack of epitaxial layers—a lightly doped (LD) n-type layer 109N epitaxially grown on fin structure 106N, a heavily doped (HD) n-type layer 110N epitaxially grown on LD n-type layer 109N, and a p-type capping layer 111N epitaxially grown on HD n-type layer 110N. In some embodiments, LD and HD n-type layers 109N-110N can include epitaxially-grown semiconductor material, such as silicon, and n-type dopants, such as phosphorus and other suitable n-type dopants. LD n-type layers 109N can include a doping concentration ranging from about 10¹⁵ atoms/cm³ to about 10¹⁸ atoms/cm³, which is lower than a doping concentration of HD n-type layers 110N, which can range from about 10¹⁹ atoms/cm³ to about 10²³ atoms/cm³. In some embodiments, HD n-type layer 110N is thicker than LD n-type layer 109N.

Similarly, each of S/D regions 108P can include a stack of epitaxial layers—a LD p-type layer 109P epitaxially grown on fin structure 106P, a HD p-type layer 110P epitaxially grown on LD p-type layer 109P, and an n-type capping layer 111N epitaxially grown on HD p-type layer 110P. In some embodiments, LD and HD p-type layers 109P-110P can include epitaxially-grown semiconductor material, such as SiGe, and p-type dopants, such as boron and other suitable p-type dopants. LD p-type layers 109P can include a doping concentration ranging from about 10¹⁵ atoms/cm³ to about 10¹⁸ atoms/cm³, which is lower than a doping concentration of HD p-type layers 110P, which can range from about 10¹⁹ atoms/cm³ to about 10²³ atoms/cm³. In some embodiments, LD p-type layers 109P can include a Ge concentration ranging from about 5 atomic percent to about 45 atomic percent, which is lower than a Ge concentration of HD p-type layers 110P, which can range from about 50 atomic percent to about 80 atomic percent. In some embodiments, HD p-type layer 110P is thicker than LD p-type layer 109P.

Referring to FIGS. 2A and 2C, S/D contact structure 120N is disposed on S/D region 108N and within ESL 117 and ILD layers 118A-118B. In some embodiments, S/D contact structure 120N can include (i) an nWFM silicide layer 132N with a first portion disposed within HD n-type layer 110N, and a second portion disposed within p-type capping layer 111N and in contact with ESL 117, (ii) a contact plug 134N with a first portion disposed within nWFM silicide layer 132N, a second portion surrounded by ESL 117, and a third portion disposed within ILD layers 118A-118B, and (iii) a carbon-based barrier layer 136N disposed along sidewalls of the third portion of contact plug 134N.

In some embodiments, nWFM silicide layer 132N can include a metal or a metal silicide with a work function value closer to a conduction band-edge energy than a valence band-edge energy of the material of HD n-type layer 110N. For example, the metal or the metal silicide can have a work function value less than 4.5 eV (e.g., about 3.5 eV to about 4.4 eV), which can be closer to the conduction band energy (e.g., 4.1 eV of Si or 3.8 eV of SiGe) than the valence band energy (e.g., 5.2 eV of Si or 4.8 eV of SiGe) of Si-based or SiGe-based material of HD n-type layer 110N. In some embodiments, the metal silicide of nWFM silicide layer 132N can include titanium silicide (TiₓSi_{y}), tantalum silicide (TaₓSi_{y}), molybdenum (MoₓSi_{y}), zirconium silicide (ZrₓSi_{y}), hafnium silicide (HfₓSi_{y}), scandium silicide (ScₓSi_{y}), yttrium silicide (YₓSi_{y}), terbium silicide (TbₓSi_{y}), lutetium silicide (LuₓSi_{y}), erbium silicide (ErₓSi_{y}), ybtterbium silicide (YbₓSi_{y}), europium silicide (EuₓSi_{y}), thorium silicide (ThₓSi_{y}), (TiₓSb_{y}Si_{z}), or a combination thereof.

In some embodiments, contact plug 134N can include conductive materials, such as cobalt (Co), tungsten (W), ruthenium (Ru), iridium (Ir), nickel (Ni), osmium (Os), rhodium (Rh), aluminum (Al), molybdenum (Mo), copper (Cu), zirconium (Zr), stannum (Sn), silver (Ag), gold (Au), zinc (Zn), cadmium (Cd), and a combination thereof.

Referring to FIGS. 2B and 2D, S/D contact structure 120P is disposed on S/D region 108P. In some embodiments, S/D contact structure 120P can include (i) a pWFM silicide layer 131 with a first portion disposed within HD p-type layer 110P, and a second portion disposed within capping layer 111P and in contact with ESL 117, (ii) an nWFM silicide layer 132P disposed on pWFM silicide layer 131 and surrounded by ESL 117, (iii) a contact plug 134P disposed on nWFM silicide layer 132P and within ILD layers 118A-118B, and (iv) a carbon-based barrier layer 136P disposed along sidewalls of contact plug 134P. The height of contact plug 134N along a Z-axis is greater than the height of contact plug 134P along a Z-axis by about a thickness of nWFM silicide layer 132P along a Z-axis. The discussion of contact plug 134N applies to contact plug 134P, unless mentioned otherwise.

In some embodiments, pWFM silicide layer 131 can include a metal or a metal silicide with a work function value closer to a valence band-edge energy than a conduction band-edge energy of the material of HD p-type layer 110P. For example, the metal or the metal silicide can have a work function value greater than 4.5 eV (e.g., about 4.5 eV to about 5.5 eV), which can be closer to the valence band energy (e.g., 5.2 eV of Si or 4.8 eV of SiGe) than the conduction band energy (e.g., 4.1 eV of Si or 3.8 eV of SiGe) of Si-based or SiGe-based material of HD p-type layer 110P. In some embodiments, the metal silicide of pWFM silicide layer 131 can include nickel silicide (NiₓSi_{y}), cobalt silicide (CoₓSi_{y}), manganese silicide (MnₓSi_{y}), tungsten silicide (WₓSi_{y}), iron silicide (FeₓSi_{y}), rhodium silicide (RhₓSi_{y}), palladium silicide (PdₓSi_{y}), ruthenium silicide (RuₓSi_{y}), platinum silicide (PtₓSi_{y}), iridium silicide (IrₓSi_{y}), osmium silicide (OsₓSi_{y}), TiGaSiGe or metalₓSi_{y}Ge_{z}, or a combination thereof. The metal silicide of pWFM silicide layer 131 is different from the metal silicide of nWFM silicide layers 132N-132P and can have a work function value greater than the work function values of nWFM silicide layers 132N-132P. In some embodiments, nWFM silicide layer 132P can be formed at the same time as nWFM silicide layer 132N and can include a metal silicide similar to nWFM silicide layer 132N. In some embodiments, thickness of nWFM silicide layer 132N is greater than thickness of nWFM silicide layer 132P.

In some embodiments, carbon-based barrier layers 136N-136P (also referred to as “carbide barrier layers 136N-136P”) can include a carbide material with a carbide-to-oxide etch selectivity of about 40 to about 100 or greater than about, a density greater than about 1.7 gm/cm³ (e.g., about 1.71 gm/cm³ to about 2.5 gm/cm³), and a dielectric constant less than about 5 (e.g., about 3 to about 4.9). The high density and high carbide-to-oxide etch selectivity can prevent or minimize etching of carbide barrier layers 136N-136P during the formation of silicide layers 131 and 132N-132P, as described in detail below. In some embodiments, carbide barrier layers 136N-136P have a higher etch selectivity over oxide and a higher density than nitride barrier layers. As a result, carbide barrier layers 136N-136P with smaller thicknesses (e.g., about 2 to about 5 times smaller) than nitride barrier layers can be formed to adequately protect adjacent FET structures during the formation of silicide layers 131 and 132N-132P and provide electrical isolation between S/D contact structures 120N-120P and the adjacent FET structures. Also, due to lower dielectric constant of carbide barrier layers 136N-136P compared to that of nitride barrier layers (e.g., dielectric constant of SiN about 7), carbide barrier layers 136N-136P with thicknesses smaller than that of nitride barrier layers can be formed without increasing parasitic capacitances of NFET 102N and PFET 102P. In some embodiments, carbon-based barrier layers 136N-136P can have a thickness T1 of about 1 nm to about 4 nm. If thickness T1 is below 1 nm, carbon-based barrier layers 136N-136P may not adequately protect adjacent FET structures during the formation of silicide layers 131 and 132N-132P. On the other hand, if thickness T1 is greater than 4 nm, the device size increases, and consequently, increases device manufacturing cost.

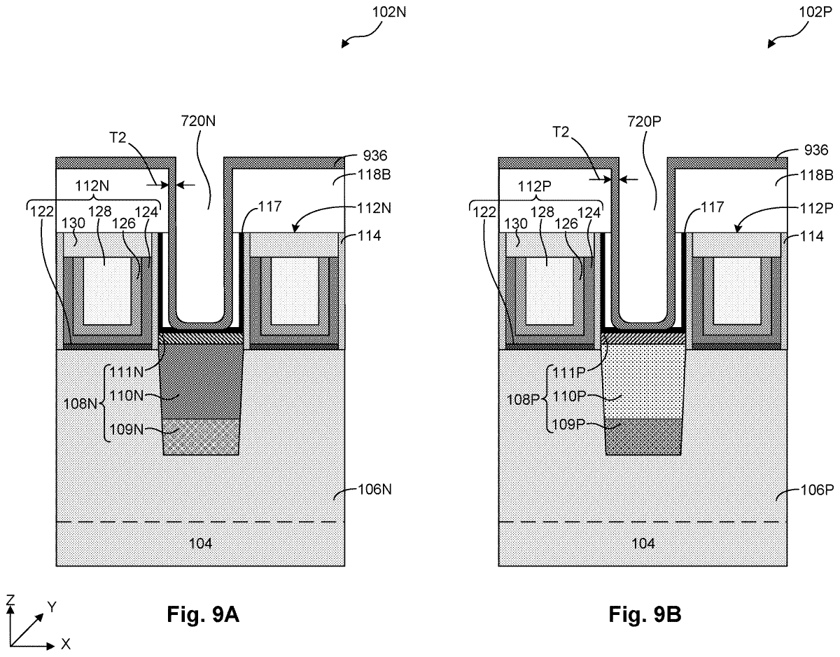

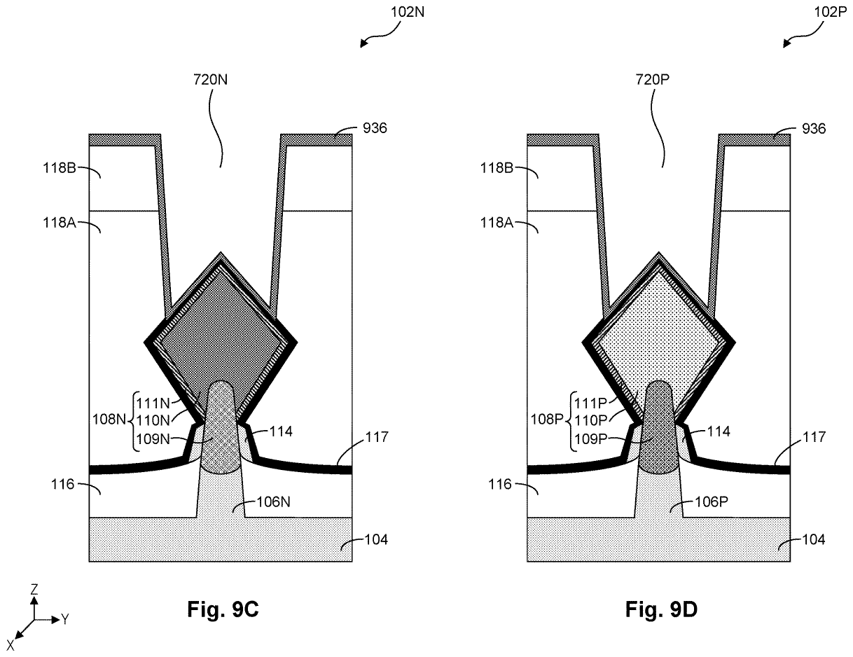

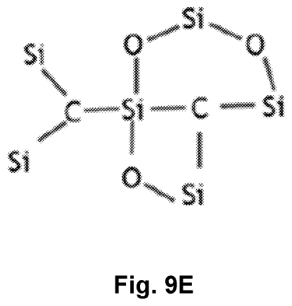

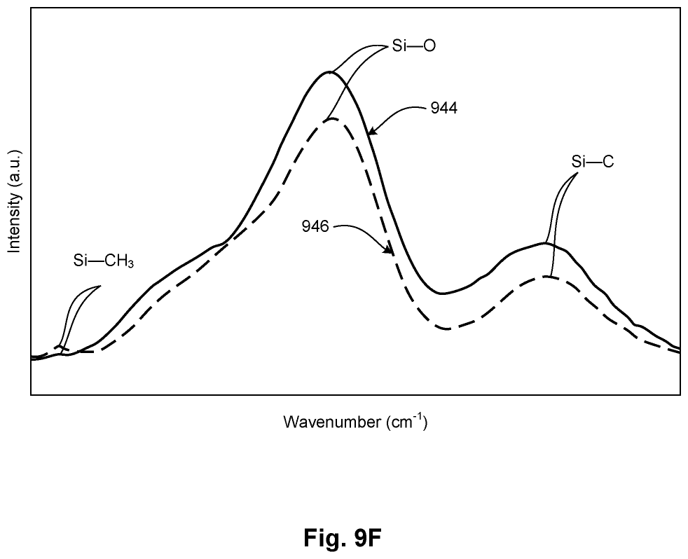

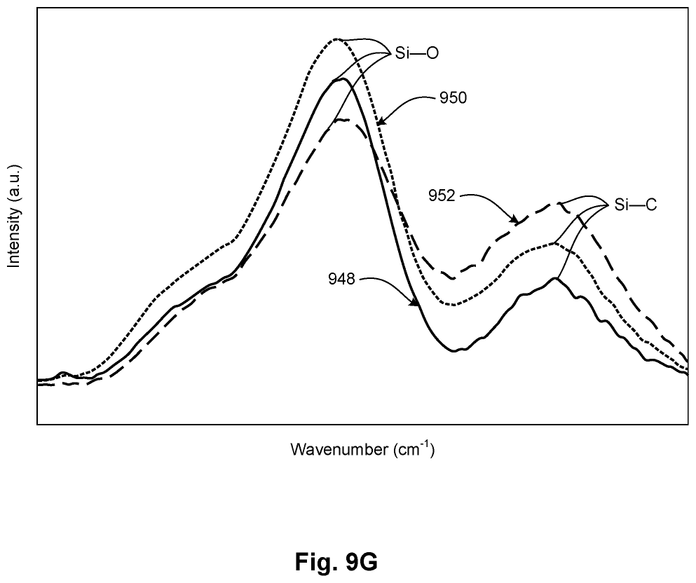

In some embodiments, carbon-based barrier layers 136N-136P can include only silicon-carbon (Si—C) bonds or only a combination of Si—C and silicon-oxygen (Si—O) bonds, as shown in FIG. 9E. The Si—C bonds can provide carbon-based barrier layers 136N-136P with a greater chemical stability, thermal stability, resistance to etching, resistance to oxygen diffusion, and etch selectivity over oxide compared to nitride barrier layers (e.g., silicon nitride (SiN) barrier layers). In some embodiments, the carbide material of carbon-based barrier layers 136N-136P can include undoped silicon carbide (SiC) or doped silicon carbide, such as oxygen doped silicon carbide (SiOC), and nitrogen and oxygen doped silicon carbide (SiOCN). In some embodiments, the carbide material can include (i) SiOC with a silicon concentration of about 25 atomic % to about 35 atomic %, a carbon concentration of about 10 atomic % to about 40 atomic %, and an oxygen concentration ranging of 30 atomic % to about 55 atomic %, and a silicon to oxygen to carbon ratio (Si: O: C) of about 1:1:0.2 to about 1:3:1, or (ii) SiOCN with a silicon to carbon to oxygen to nitrogen ratio (Si:C:O:N) of about 1:0.1:0.9:05 to about 1:0.8:1.6:1 to exhibit a carbide-to-oxide etch selectivity of about 40 to about 100 or greater than about, a density of about 1.7 gm/cm³ to about 2.5 gm/cm³, and a dielectric constant of about 3 to about 4.9.

Referring to FIGS. 2E-2F, in some embodiments, NFET 102N can be an n-type gate-all-around (GAA) FET 102N instead of n-type finFET 102N shown in FIGS. 2A and 2C, and PFET 102P can be a p-type GAA FET 102P instead of p-type finFET 102P shown in FIGS. 2B and 2D. For GAA FETs 102N-102P, gate structures 112N-112P can have cross-sectional views as shown in FIGS. 2E-2F. Gate structures 112N-112P of GAA FETs 102N-102P can be wrapped around nanostructured channel regions 121. As used herein, the term “nanostructured” defines a structure, layer, and/or region as having a horizontal dimension (e.g., along an X-and/or Y-axis) and/or a vertical dimension (e.g., along a Z-axis) less than about 100 nm, for example about 90 nm, about 50 nm, about 10 nm, or other values less than about 100 nm are within the scope of the disclosure.

Nanostructured channel regions 121 can include semiconductor materials similar to or different from substrate 104. In some embodiments, nanostructured channel regions 121 can include Si, SiAs, silicon phosphide (SiP), SiC, SiCP, SiGe, silicon germanium boron (SiGeB), germanium boron (GeB), silicon germanium stannum boron (SiGeSnB), a III-V semiconductor compound, or other suitable semiconductor materials. Though rectangular cross-sections of nanostructured channel regions 121 are shown, nanostructured channel regions 121 can have cross-sections of other geometric shapes (e.g., circular, elliptical, triangular, or polygonal). Gate portions of gate structures 112N-112P surrounding nanostructured channel regions 121 can be electrically isolated from adjacent S/D regions 108N-108P by inner spacers 113. Inner spacers 113 can include an insulating material, such as SiOₓ, SiN, SiCN, SiOCN, and other suitable insulating materials.

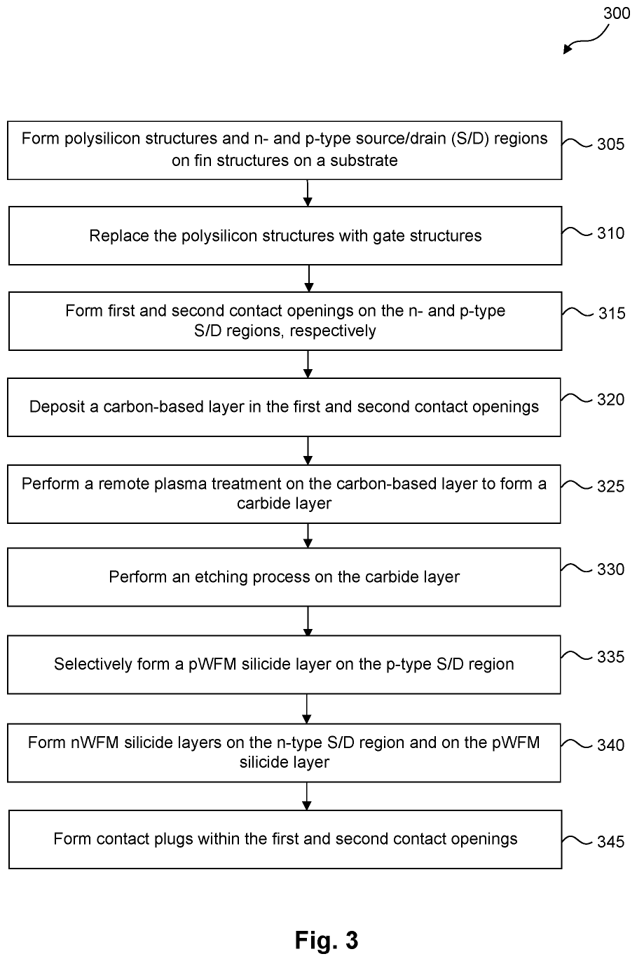

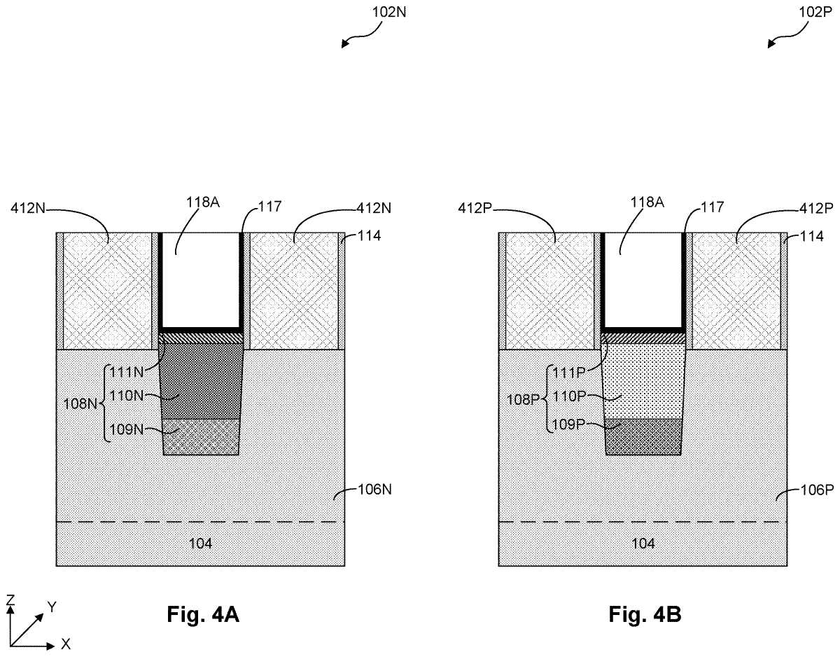

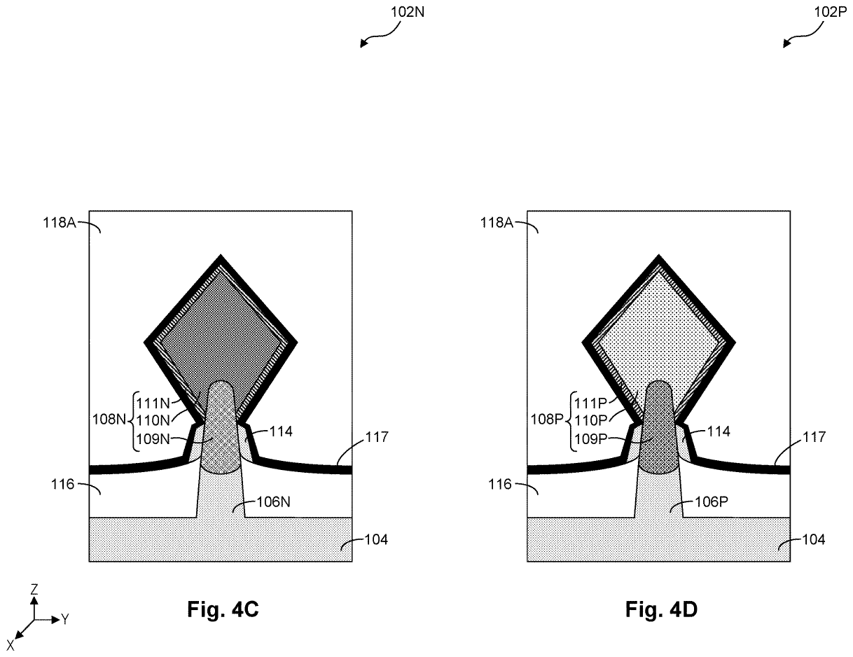

FIG. 3 is a flow diagram of an example method 300 for fabricating NFET 102N and PFET 102P of semiconductor device 100, according to some embodiments. For illustrative purposes, the operations illustrated in FIG. 3 will be described with reference to the example fabrication process for fabricating NFET 102N and PFET 102P as illustrated in FIGS. 4A-16D. FIGS. 4A-16A and 4C-16C are cross-sectional views of NFET 102N along respective lines A-A and C-C of FIG. 1, and FIGS. 4B-16B and 4D-16D are cross-sectional views of PFET 102P along respective lines B-B and D-D of FIG. 1 at various stages of fabrication, according to some embodiments. Operations can be performed in a different order or not performed depending on specific applications. It should be noted that method 300 may not produce a complete NFET 102N and PFET 102P. Accordingly, it is understood that additional processes can be provided before, during, and after method 300, and that some other processes may only be briefly described herein. Elements in FIGS. 4A-16D with the same annotations as elements in FIGS. 1 and 2A-2D are described above.

In operation 305, polysilicon structures and n-and p-type S/D regions are formed on fin structures on a substrate. For example, as shown in FIGS. 4A-4B, polysilicon structures 412N-412P and S/D regions 108N-108P are formed on fin structures 106N-106P, which are formed on substrate 104. During subsequent processing, polysilicon structures 412N-412P can be replaced in a gate replacement process to form gate structures 112N-112P. In some embodiments, the formation of S/D regions 108N-108P can include sequential operations of (i) forming S/D openings (not shown) in portions of fin structures 106N-106P that are not underlying polysilicon structures 7412N-412P, (ii) patterning a masking layer (e.g., a photoresist layer; not shown) to cover the S/D opening in fin structure 106P, (iii) selectively epitaxially growing a Si layer (not shown) within S/D opening in fin structure 106N, (iv) selectively doping the Si layer with n-type dopants (e.g., phosphorus) to form LD and HD n-type layers 109N-110N, as shown in FIGS. 4A and 4C, (v) selectively epitaxially growing a SiGe layer (not shown) on HD n-type layer 110N or lightly doped p-type capping layer on HD p-type layer 110P, (vi) selectively doping the SiGe layer with p-type dopants (e.g., boron) to form p-type capping layer 111N, as shown in FIGS. 4A and 4C, (vii) removing the masking layer from the S/D opening in fin structure 106P, (viii) patterning a masking layer to cover S/D region 108N, (ix) selectively epitaxially growing a SiGe layer (not shown) within S/D opening in fin structure 106P, (x) selectively doping the SiGe layer with p-type dopants (e.g., boron) to form LD and HD p-type layers 109P-110P, as shown in FIGS. 4B and 4D, and (xi) selectively epitaxially growing a Si layer (not shown) on HD p-type layer 110P. After the formation of S/D regions 108N-108P, ESL 117 and ILD layer 118A can be formed to form the structures of FIGS. 4A-4D.

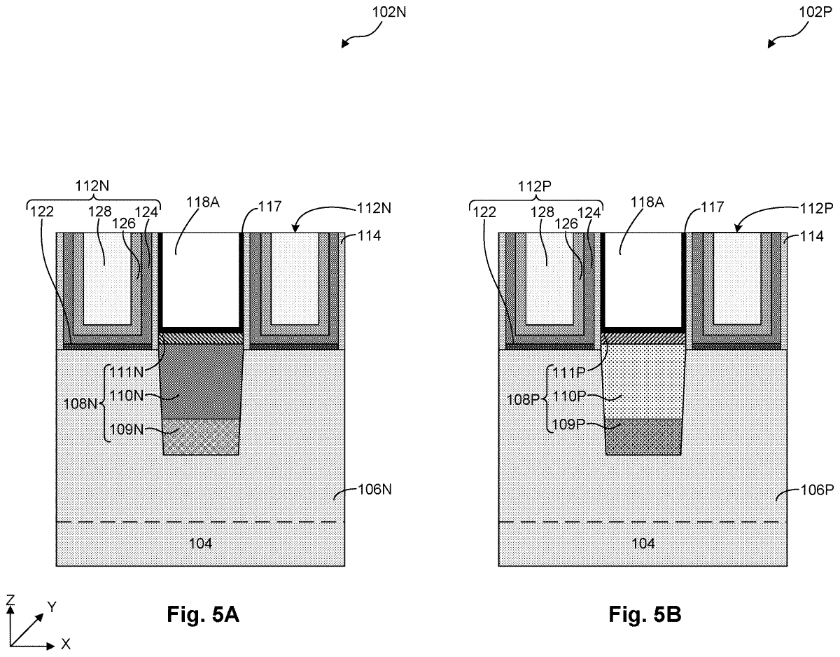

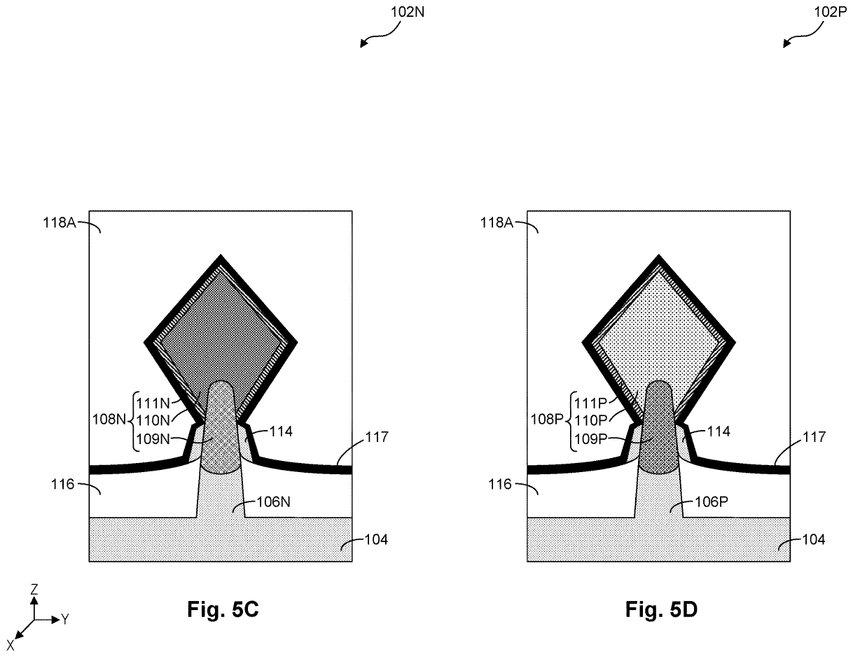

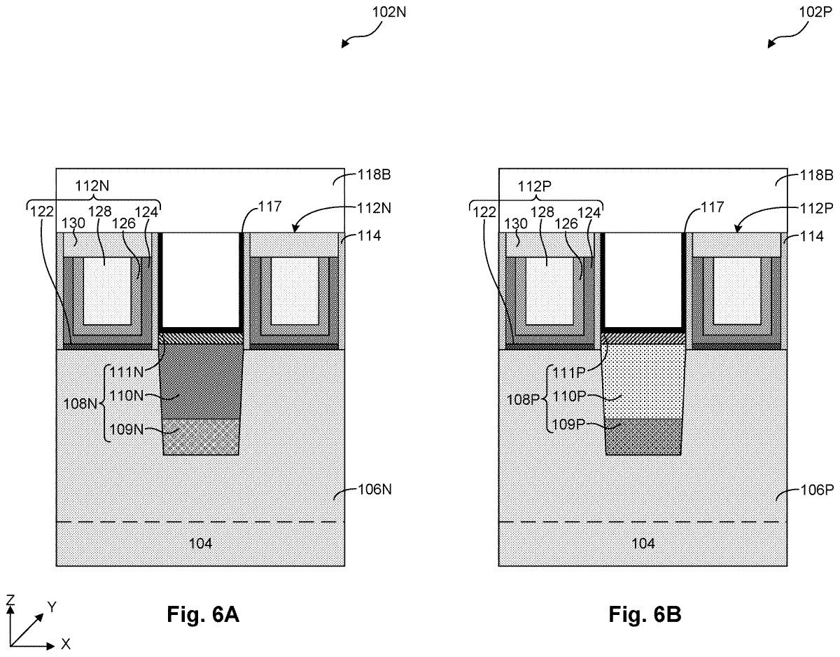

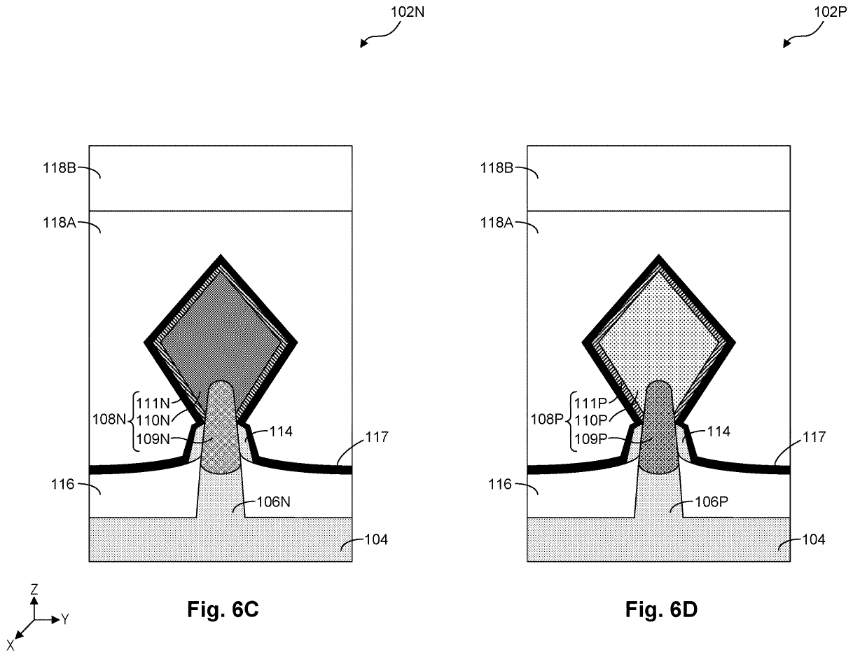

Referring to FIG. 3, in operation 310, polysilicon structures are replaced with gate structures. For example, as shown in FIGS. 5A-5B, polysilicon structures 412N-412P are replaced with gate structures 112N-112P. In some embodiments, gate structures 112N-112P can be etched back to form gate capping layers 130, as shown in FIGS. 6A-6B. After the formation of gate capping layers 130, ILD layer 118B can be formed to form the structures of FIGS. 6A-6D.

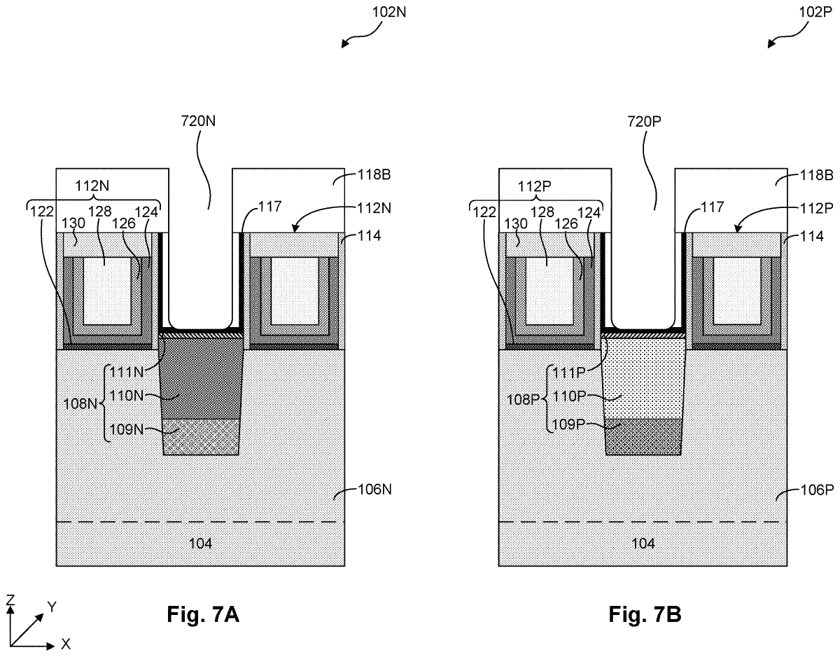

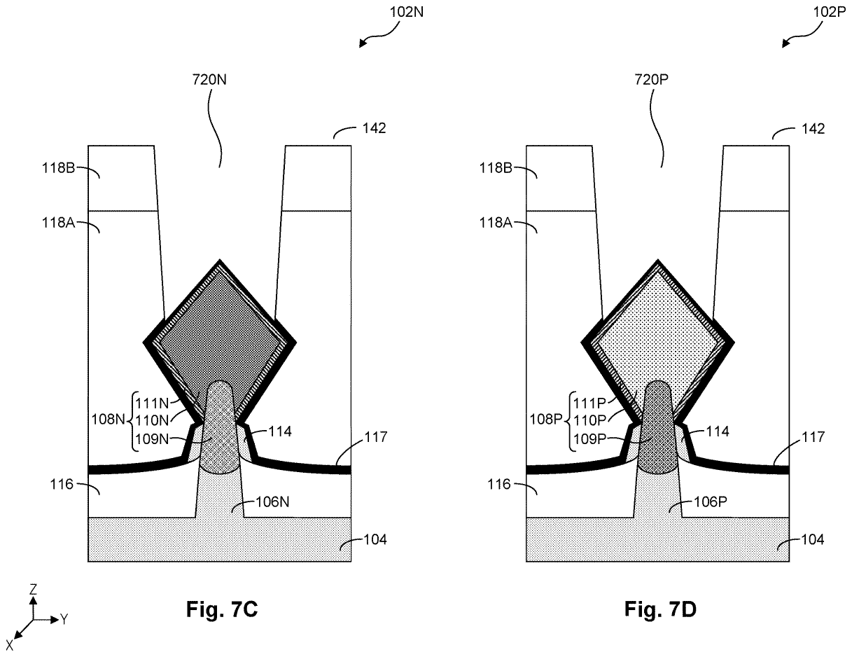

Referring to FIG. 3, in operation 315, first and second contact openings are formed on the n-and p-type source S/D regions. For example, as shown in FIGS. 7A-7D, first and second contact openings 720N-720P are formed on S/D regions 108N-108P by etching portions of ESL 117 and ILD layers 118A-118B on S/D regions 108N-108P.

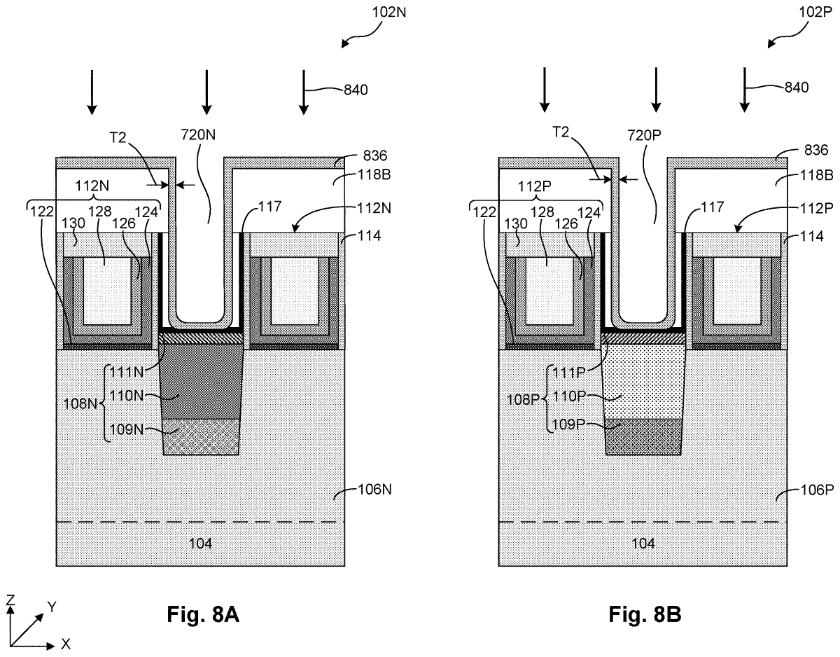

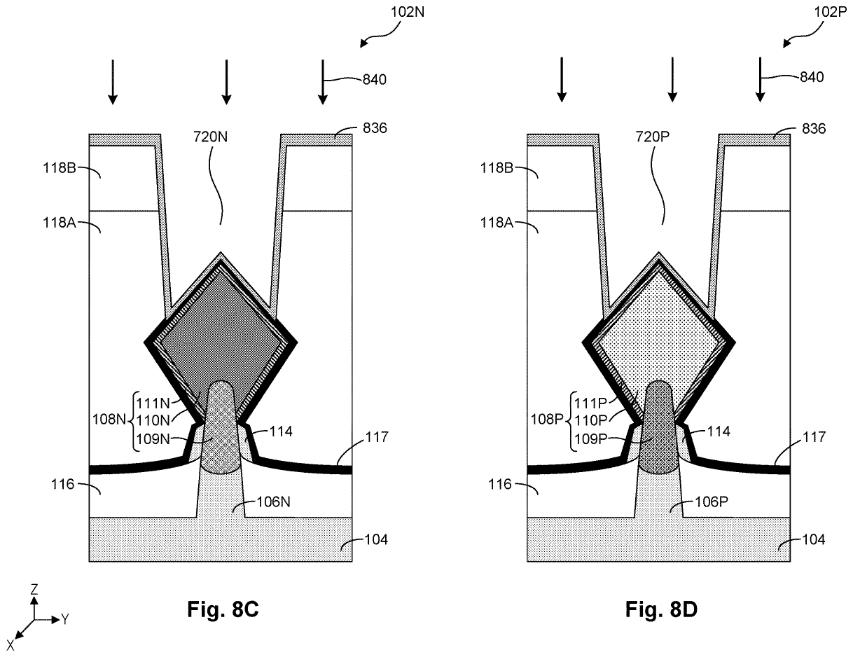

Referring to FIG. 3, in operations 320-330, carbon-based barrier layers are formed along sidewalls of the first and second contact openings. For example, carbon-based barrier layers 136N-136P are formed along sidewalls of first and second contact openings 720N-720P in operations 320-330, as described below with reference to FIGS. 8A-8D, 9A-9G, and 10A-10D.

Referring to FIG. 3, in operation 320, a carbon-based layer is deposited in the first and second contact openings. For example, as shown in FIGS. 8A-8D, a carbon-based layer 836 is substantially conformally deposited in first and second contact openings 720N-720P with a step coverage (i.e., ratio of thickness of carbon-based layer 836 on ILD layer 118B to thickness of carbon-based layer 836 on ESL 117) of about 85% to about 99%. In some embodiments, carbon-based layer 836 can be a carbide layer deposited in a chemical vapor deposition (CVD) process chamber or an atomic layer deposition (ALD) process chamber by exposing the structures of FIGS. 7A-7D to a carbon-based precursor in a deposition process chamber at a temperature of about 200 °C to about 700 °C, at a pressure of about 0.5 Torr to about 12 Torr, and at a power of about 700 watt to about 3000 watt. In some embodiments, carbon-based layer 836 can have a thickness T2 of about 1.5 nm to about 4.5 nm. In some embodiments, the carbon-based precursor can include a silicon-, oxygen-, hydrogen-, and carbon-containing precursor with (i) one or more Si—C—Si bonds, Si—O bonds, and silicon-methyl group (Si—CH₃) bonds, or (ii) one or more Si—O—Si bonds, Si—H bonds, and Si—CH₃ bonds. In some embodiments, the carbon-based precursor can be a linear siloxane, such as pentamethyldisiloxane (PMDSO), tetramethyldisiloxane (TMDSO), hexamethyltrisiloxane, and heptamethyltrisiloxane.

In some embodiments, the internal structure of the carbon-based precursor is substantially maintained in the chemical structure of carbon-based layer 836 and the Si—C and Si—O bonds of the carbon-based precursor are substantially preserved in the chemical structure of carbon-based layer 836. The deposition process conditions can selectively break the Si—H of the carbon-based precursor to extract hydrogen from the broken Si—H bonds without extracting oxygen from the Si—O bonds or carbon from the Si—C bonds of the carbon-based precursor. In some embodiments, along with Si—C and Si—O bonds, the chemical structure of carbon-based layer 836 can include one or more silicon—hydroxyl group (Si—OH) bonds, one or more terminal Si—CH₃ bonds, and one or more terminal Si—H bonds.

The hydrogen content in carbon-based layer 836 lowers its material properties, such as chemical stability, thermal stability, resistance to etching, resistance to oxygen diffusion, and etch selectivity over oxide. To improve the material properties of carbon-based layer 836 and exhibit a carbide-to-oxide etch selectivity of about 40 to about 100 or greater than about 100, a density of about 1.7 gm/cm³ to about 2.5 gm/cm³, and a dielectric constant of about 3 to about 4.9, a remote plasma treatment can be performed on carbon-based layer 836, as described below with respect to operation 325 of FIG. 3. The remote plasma treatment can substantially decrease the hydrogen atoms and increase the bond density of Si—C and/or Si—O bonds in carbon-based layer 836. The decreased hydrogen content and increased Si—C bond density can improve the material properties of carbon-based layer 836, which forms carbon-based barrier layers 136N-136P in subsequent processing.

Referring to FIG. 3, in operation 325, a remote plasma treatment is performed on the carbon-based layer to form a carbide layer. For example, as described with respect to FIGS. 8A-8D and 9A-9G, a remote plasma treatment is performed on carbon-based layer 836 to form a hydrogen-free (e.g., hydrogen concentration zero, substantially zero, or between about 0.001 atomic % to about 0.1 atomic %) carbide layer 936 in first and second contact openings 720N-720P. Carbide layer 936 can exhibit a carbide-to-oxide etch selectivity of about 40 to about 100 or greater than about 100, a density of about 1.7 gm/cm³ to about 2.5 gm/cm³, and a dielectric constant of about 3 to about 4.9.

The remote plasma treatment can include sequential operations of (i) flowing source gases of hydrogen and oxygen into a remote plasma source chamber (not shown), (ii) flowing an inert gas with the source gases of hydrogen and oxygen, (iii) generating radicals of hydrogen and oxygen atoms from the source gases of hydrogen and oxygen, respectively, in the remote plasma source chamber, and (iv) flowing the radicals of hydrogen and oxygen atoms 840 into the deposition process chamber (not shown) and on carbon-based layer 836, as shown in FIGS. 8A-8D. In some embodiments, the inert gas can be supplied into the remote plasma source chamber substantially at the same time as the source gases of hydrogen and oxygen. The deposition and remote plasma treatment of carbon-based layer 836 can be an in-situ process, which is performed without introducing a vacuum break between the deposition process and the remote plasma treatment.

In some embodiments, carbide layer 936 formed after the remote plasma treatment with hydrogen and oxygen radicals can include silicon-carbon (Si—C) bonds or a combination of Si—C and Si—O bonds without any Si—OH, Si—CH₃, and/or Si—H bonds, as shown in FIG. 9E. In some embodiments, carbide layer 936 can include undoped silicon carbide (SiC) or doped silicon carbide, such as oxygen doped silicon carbide (SiOC), and nitrogen and oxygen doped silicon carbide (SiOCN). In some embodiments, carbide layer 936 can include (i) SiOC with a silicon concentration of about 25 atomic % to about 35 atomic %, a carbon concentration of about 10 atomic % to about 40 atomic %, and an oxygen concentration ranging of 30 atomic % to about 55 atomic %, and a silicon to oxygen to carbon ratio (Si:O:C) of about 1:1:0.2 to about 1:3:1, or (ii) SiOCN with a silicon to carbon to oxygen to nitrogen ratio (Si:C:O:N) of about 1:0.1:0.9:05 to about 1:0.8:1.6:1. In some embodiments, to form carbide layer 936 with the carbon concentration of about 10 atomic % to about 40 atomic %, the source gases of hydrogen and oxygen are supplied to the remote plasma source chamber at a hydrogen to oxygen (H₂:O₂) gas flow rate ratio of about 20 to about 100.

The remote plasma treatment with hydrogen and oxygen radicals can remove hydrogen atoms from Si—CH₃, Si—OH, and/or Si—H bonds in carbon-based layer 836, and promote cross-linking to form additional Si—C—Si and Si—O—Si bonds, while substantially preserving the existing Si—C and Si—O bonds in carbon-based layer 836. As a result, the bond density of Si—C and Si—O bonds increases and the bond density of terminal Si—CH₃, Si—OH, and/or Si—H bonds decreases in carbide layer 936 compared to that in carbon-based layer 836, as shown in FIG. 9F. FIG. 9F shows (i) the vibration peaks of Si—O and Si—C bonds in a Fourier-Transform infrared spectroscopy (FTIR) spectrum 944 of carbide layer 936 are higher than the vibration peaks of Si—O and Si—C bonds in an FTIR spectrum 946 of carbon-based layer 836, and (ii) the vibration peak of Si—CH₃ bonds in FTIR spectrum 944 is lower than the vibration peak of Si—CH₃ bonds in FTIR spectrum 946. The higher vibration peaks of Si—O and Si—C bonds correspond to a larger number of Si—O and Si—C bonds per unit volume of carbide layer 936 than that of carbon-based layer 836. The lower vibration peak of Si—CH₃ bonds corresponds to a smaller number of Si—CH₃ bonds per unit volume of carbide layer 936 than that of carbon-based layer 836.

The increase in Si—C bonds and decrease in terminal Si—CH3, Si—OH, and/or Si—H bonds increases the density, chemical stability, thermal stability, resistance to etching, resistance to oxygen diffusion, and etch selectivity over oxide of carbide layer 936 compared to that of carbon-based layer 836. In some embodiments, carbide layer 936 may not have any Si—CH3, Si—OH, and/or Si—H bonds. In some embodiments, water (H₂O) and carbon-di-oxide (CO₂) can be formed as by products when oxygen radicals react with Si—CH3, Si—OH, and/or Si—H bonds during the remote plasma treatment. In some embodiments, the remote plasma treatment can remove dangling silicon and/or carbon bonds in carbon-based layer 836 and promote cross-linking of silicon and carbon atoms to form Si—C—Si bonds carbide layer 936.

The bond density of Si—C and Si—O bonds can be tuned by tuning the hydrogen to oxygen gas flow rate ratio, which corresponds to the hydrogen to oxygen radical concentration ratio, as shown in FIG. 9G. FIG. 9G shows an FTIR spectrum 948 of carbon-based layer 836, and FTIR spectra 950 and 952 of carbide layer 936 formed with first and second hydrogen to oxygen gas flow rate ratios, respectively. The second hydrogen to oxygen gas flow rate ratio is greater than the first hydrogen to oxygen gas flow rate ratio. In some embodiments, carbide layer 936 formed with the first hydrogen to oxygen gas flow rate ratio can have higher Si—O and Si—C bond vibration peaks (FTIR spectra 950) than those of carbon-based layer 836, which correspond to a higher density of Si—O and Si—C bonds in carbide layer 936 than that in carbon-based layer 836. In some embodiments, carbide layer 936 formed with the second hydrogen to oxygen gas flow rate ratio can have a higher Si—C bond vibration peak and a lower Si—O bond vibration peak (FTIR spectra 952) than that of carbon-based layer 836, which corresponds to a higher density of Si—C bonds and a lower density of Si—O bonds in carbide layer 936 than that in carbon-based layer 836.

In some embodiments, operations 320 and 325 can be performed substantially at the same time instead of sequentially. In some embodiments, the deposition and remote plasma treatment of carbon-based layer 836 can be performed substantially at the same time by flowing the carbon-based precursor and the radicals of hydrogen and oxygen atoms 840 into the deposition process chamber substantially at the same time.

In some embodiments, operations 320 and 325 can be repeated in an alternating sequence to form hydrogen-free carbide layer 936 in a layer-by-layer approach. In each cycle of operations 320 and 325, a hydrogen-free carbide layer similar to hydrogen-free carbide layer 936 can be formed, but with a thickness smaller than thickness T2 of carbide layer 936. The cycle of operations 320 and 325 can be repeated until a hydrogen-free carbide layer with a total thickness T2 is formed. In some embodiments, in a first cycle of operations 320 and 325, a first hydrogen-free carbide layer with a first thickness can be formed in contact openings 720N-720P. In some embodiments, in a second cycle of operations 320 and 325, a second hydrogen-free carbide layer with a second thickness can be formed on the first hydrogen-free carbide layer. The first and second thicknesses can be equal to thickness T2 of carbide layer 936. In some embodiments, carbide layer 936 can be formed in two or more cycles of operations 320 and 325. The two or more cycles of operations 320 and 325 can be performed in an in-situ process.

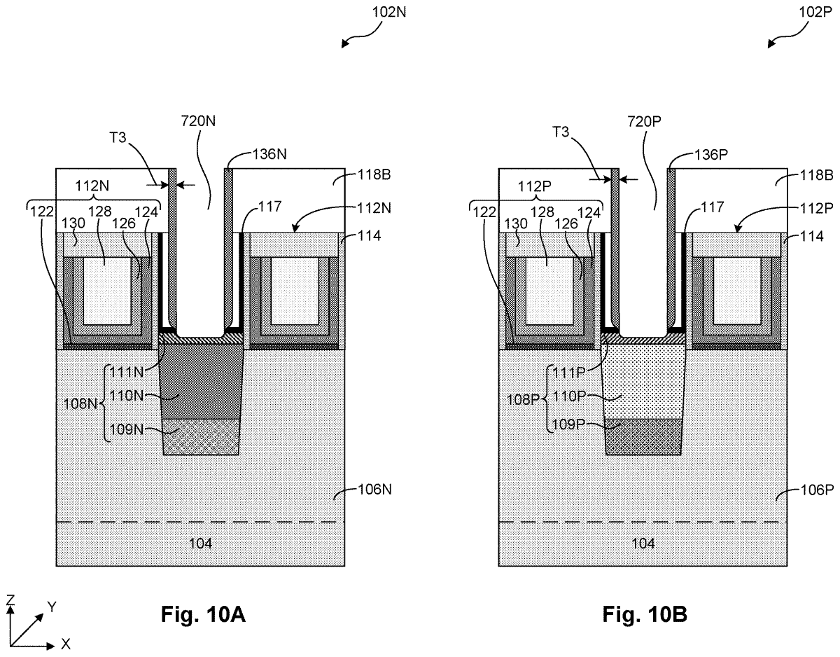

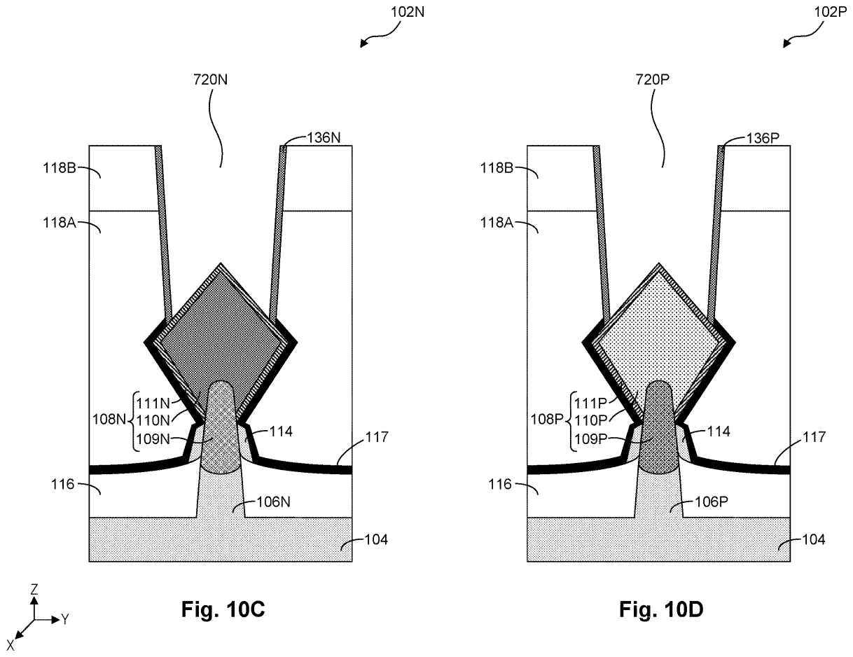

Referring to FIG. 3, in operation 330, an etching process is performed on the carbide layer. For example, as shown in FIGS. 10A-10D, an etching process is performed on carbide layer 936 to form carbon-based barrier layers 136N-136P along sidewalls of contact openings 720N-720P and expose top surfaces of n-and p-type capping layers 111N-111P within contact openings 720N-720P. The etching process can include a plasma etch process using (i) a hydrogen bromide (HBr) etching gas with helium at a temperature of about 50 °C to about 100 °C, or (ii) an etching gas mixture of fluoromethane (CH₃F) and oxygen at a temperature of about 50 °C to about 100 °C. Due to directionality provided by the plasma etch process, portions of carbide layer 936 on ILD layer 118B and on ESL 117 are removed at a faster etch rate than portions of carbide layer 936 along sidewalls of contact openings 720N-720P. As a result, portions of carbide layer 936 on ILD layer 118B and on ESL 117 are selectively removed.

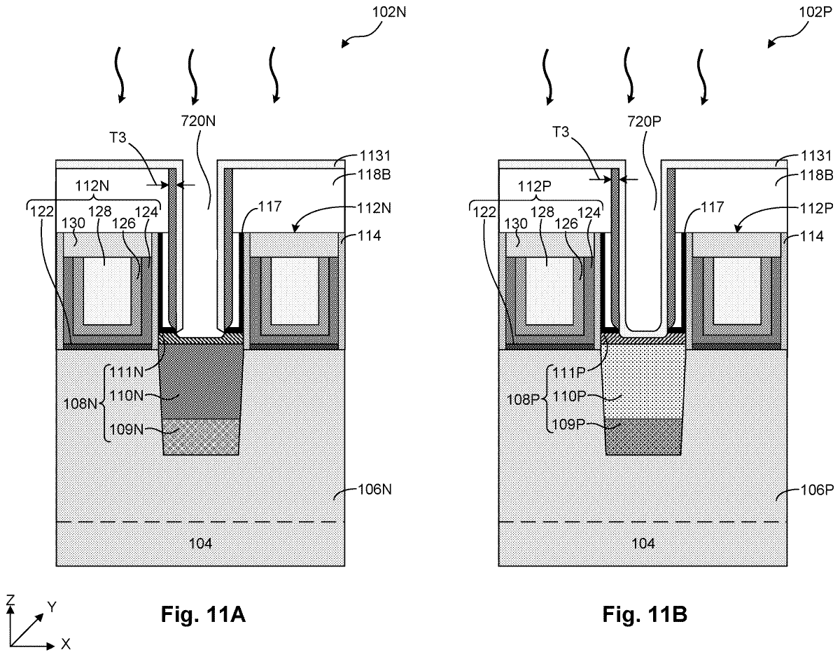

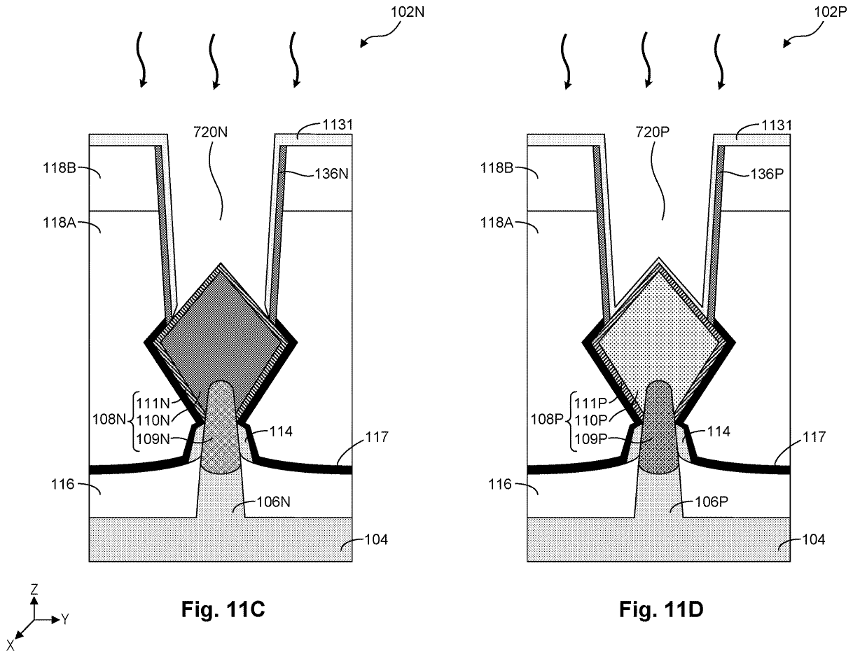

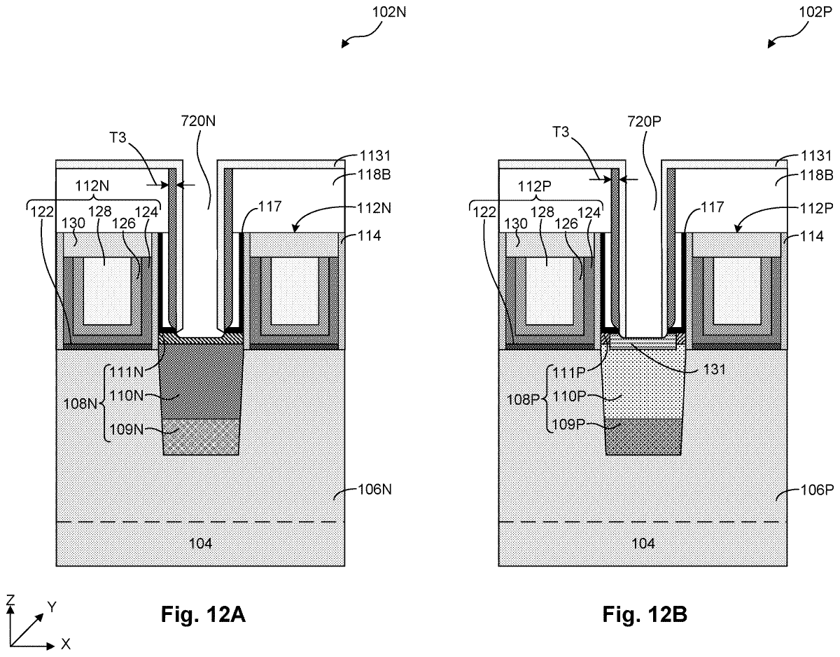

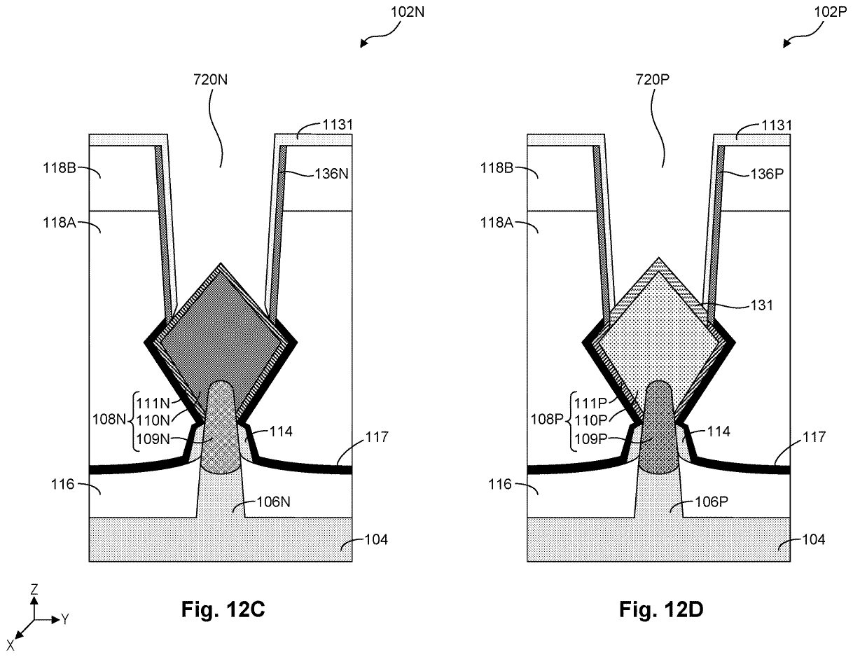

Referring to FIG. 3, in operation 335, a pWFM silicide layer is selectively formed on the p-type S/D region. For example, as described with reference to FIGS. 11A-12D, pWFM silicide layer 131 is selectively formed on S/D region 108P. The selective formation of pWFM silicide layer 131 can include sequential operations of (i) performing an etch process on the structures of FIGS. 10A-10D to remove native oxide from top surfaces of n-and p-type capping layers 111N-111P, (ii) depositing a pWFM layer 1131 on the structures of FIGS. 10A-10D after removing the native oxide to form the structures of FIGS. 11A-11D, and (iii) performing an anneal process at a temperature of about 400 °C to about 700 °C on the structures of FIGS. 11A-11D to initiate a silicidation reaction between n-type capping layer 111P and the bottom portion of pWFM layer 1131 on n-type capping layer 111P to form pWFM silicide layer 131, as shown in FIGS. 12B and 12D.

In some embodiments, performing the etch process can include performing a plasma etch process at a temperature of about 50 °C to about 100 °C with (i) an etching gas mixture of nitrogen trifluoride (NF₃) and ammonia (NH₃), or (ii) an etching gas mixture of hydrogen fluoride (HF) and ammonia (NH₃). In some embodiments, thickness of carbon-based barrier layers 136N-136P can be reduced from thickness T2 to thickness T3 by about 0.1 nm to about 0.5 nm as a result of the etch process.

In some embodiments, pWFM layer 1131 can include a work function value closer to a valence band-edge energy than a conduction band-edge energy of the material of HD p-type layer 110P of S/D region 108P. For example, pWFM layer 1131 can include a metal with a work function value greater than 4.5 eV (e.g., about 4.5 eV to about 5.5 eV), which can be closer to the valence band energy 5.2 eV of Si or 4.8 eV of SiGe than the conduction band energy 4.1 eV of Si or 3.8 eV of SiGe of HD p-type layer 110P. In some embodiments, pWFM layer 1131 can include Ni, Co, Mn, W, Fe, Rh, Pd, Ru, Pt, Ir, Os, or a combination thereof.

The deposition of pWFM layer 1131 can include depositing about 0.5 nm to about 5 nm thick pWFM layer with a chemical vapor deposition (CVD) process or an atomic layer deposition (ALD) process at a temperature ranging from about 160 °C to about 220 °C and a pressure ranging from about 5 Torr to about 10 Torr or with a lithography process and an implantation process with an energy greater than about 3 KeV and dosage of about 5×10¹⁴ to about 1×10¹⁶ ions/cm³. In some embodiments, the ALD process can include about 300 cycles to about 800 cycles, where one cycle can include sequential periods of (i) metal precursor, reactant, and carrier gas mixture flow and (ii) a gas purging process for a period of about 0.5 seconds to about 15 seconds. In some embodiments, the reactant gas can include ammonia (NH₃), carrier gas can include nitrogen or argon, and purging gas can include a noble gas.

In some embodiments, the metal precursor can include metal complexes, such as Bis(1,4-di-t-butyl-1,3-diazabutadienyl)M, M(tBuNNCHCtBuO)₂, M(eBuNNCHCiPrO)₂, and M(tBuNNCMeCMeO)₂, where M can be Ni, Co, Mn, W, Fe, Rh, Pd, Ru, Pt, Ir, or Os. As metal complexes have a higher affinity for Si than SiGe, pWFM layer 1131 deposits on n-type capping layer 111P, which includes Si and does not deposit on p-type capping layer 111N, which includes SiGe. The strained lattice structure of SiGe inhibits the adhesion of the metal complexes on p-type capping layer 111N, and as a result, prevents the formation of pWFM layer 1131 on p-type capping layer 111N of NFET 102N. Thus, the use of metal complexes as metal precursors for pWFM layer 1131 reduces the number of processing steps by eliminating the use of lithography and etching process for the selective formation of pWFM silicide layer 131 in PFET 102P, and consequently reduces the device manufacturing cost.

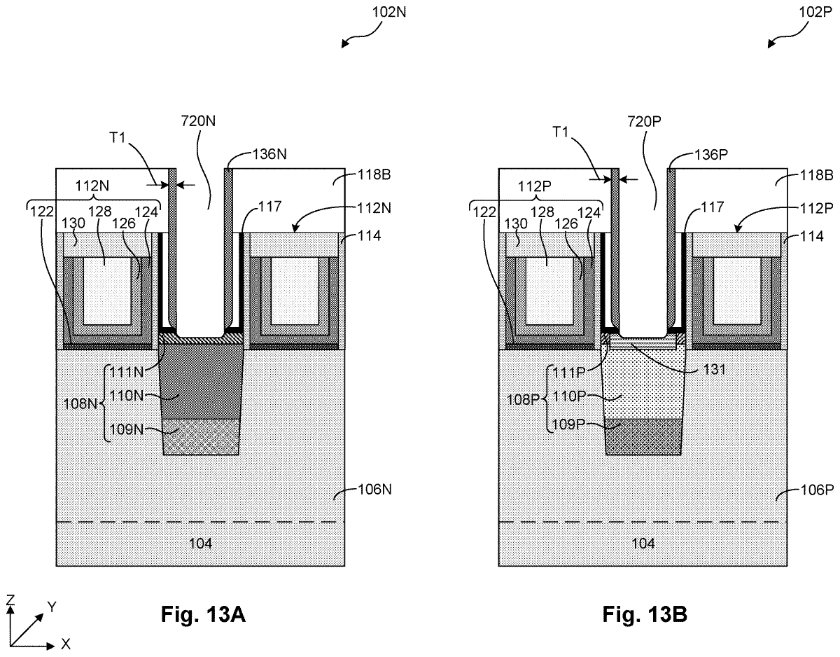

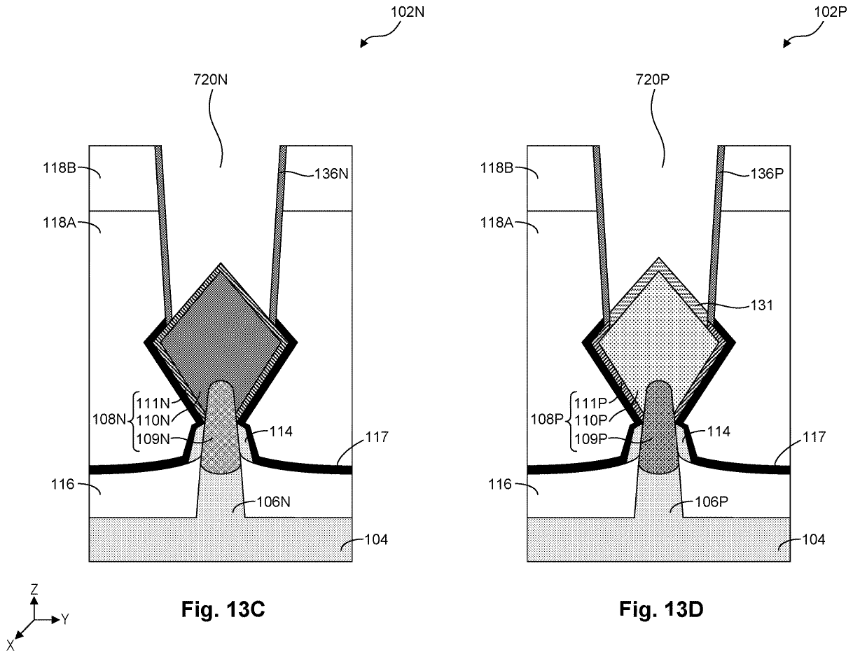

In some embodiments, after the formation of pWFM silicide layer 131, the unreacted portions of pWFM layer 1131 on sidewalls of contact openings 720N-720P can be removed by a wet etching process to form the structures of FIGS. 13A-13D.

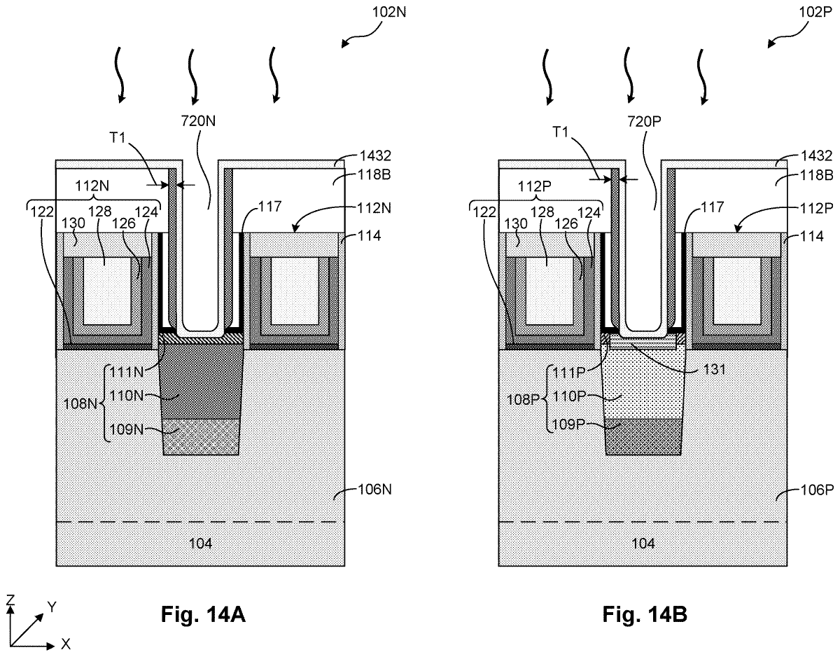

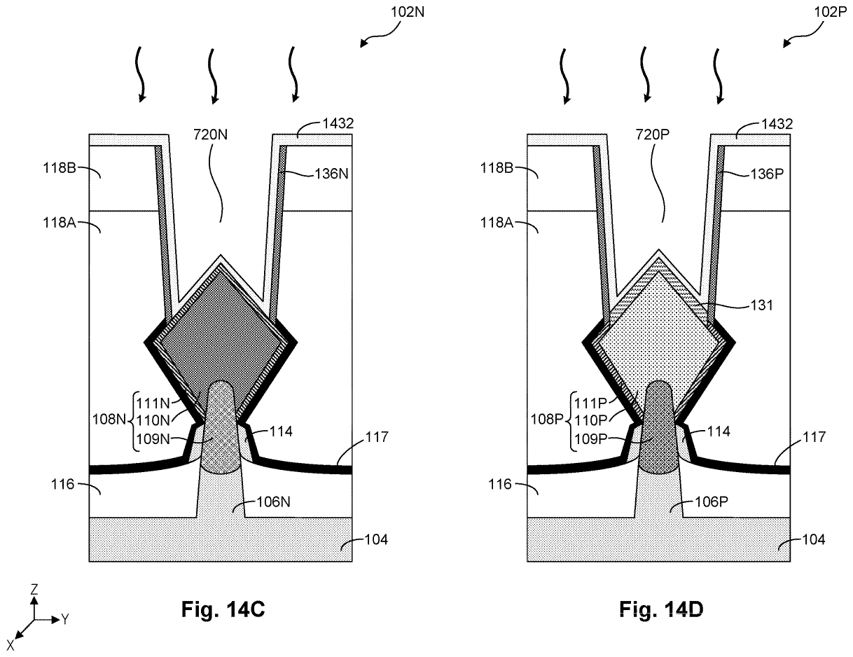

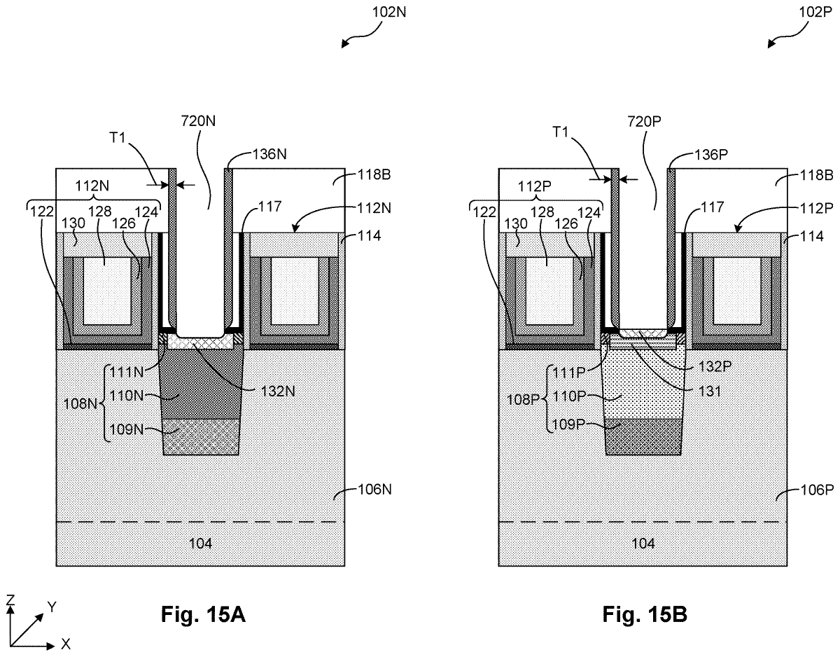

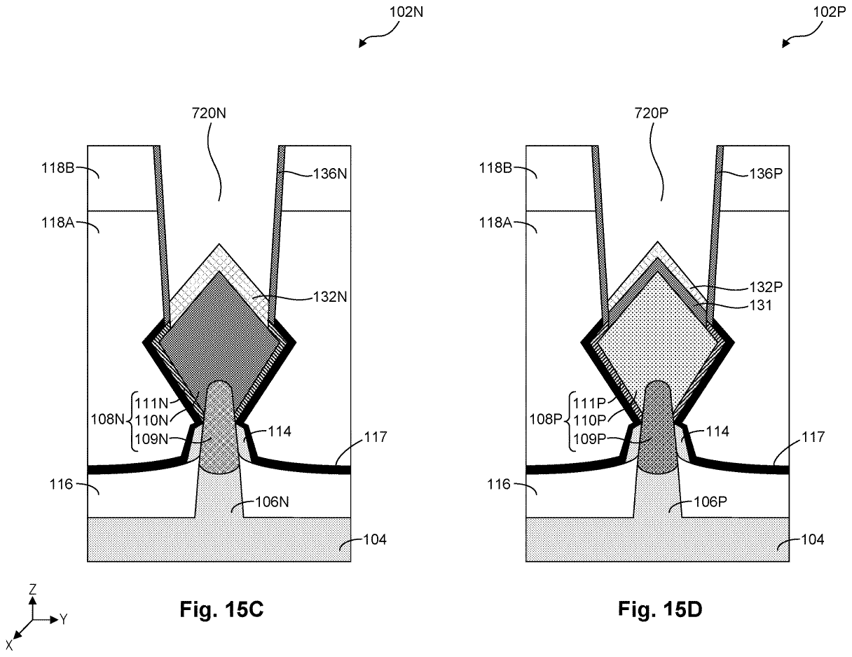

Referring to FIG. 3, in operation 340, nWFM silicide layers are formed on the n-type S/D region and on the pWFM silicide layer. For example, as described with reference to FIGS. 14A-15D, nWFM silicide layers 132N and 132P are formed on S/D region 108N and on pWFM silicide layer 131, respectively. The formation of nWFM silicide layers 132N-132P can include sequential operations of (i) performing an etch process on the structures of FIGS. 13A-13D to remove native oxide from top surfaces of p-type capping layer 111N and pWFM silicide layer 131, (ii) depositing an nWFM layer 1432 on the structures of FIGS. 13A-13D after removing the native oxide to form the structures of FIGS. 14A-14D, and (iii) performing an anneal process at a temperature of about 400 °C to about 500 °C on the structures of FIGS. 14A-14D. The anneal process can initiate silicidation reactions between (i) p-type capping layer 111N and the bottom portion of nWFM layer 1432 on p-type capping layer 111N to form nWFM silicide layer 132N, as shown in FIGS. 15A and 15C, and (ii) the bottom portion of nWFM layer 1432 within contact opening 720P and HD p-type layer 111P through pWFM silicide layer 131 to form nWFM silicide layer 132P, as shown in FIGS. 15B and 15D.

In some embodiments, the etch process to remove native oxide from top surfaces of p-type capping layer 111N and pWFM silicide layer 131 can be similar to the etch process described in operation 335 to remove native oxide. In some embodiments, thickness of carbon-based barrier layers 136N-136P can be reduced from thickness T3 to thickness T1 by about 0.1 nm to about 0.5 nm as a result of the etch process.

In some embodiments, the deposition of nWFM layer 1432 can include depositing a metal with a work function value closer to a conduction band-edge energy than a valence band-edge energy of the material of HD n-type layer 111N of S/D region 108N using a CVD process or an ALD process at a temperature ranging from about 300 °C to about 500 °C. For example, nWFM layer 1432 can include a metal with a work function value less than 4.5 eV (e.g., about 3.5 eV to about 4.4 eV), which can be closer to the conduction band energy 4.1 eV of Si or 3.8 eV of SiGe than the valence band energy 5.2 eV of Si or 4.8 eV of SiGe of HD n-type layer 111N. In some embodiments, nWFM layer 1432 can include Ti, Ta, Mo, Zr, Hf, Sc, Y, Ho, Tb, Gd, Lu, Dy, Er, Yb, or a combination thereof.

In some embodiments, after the formation of nWFM silicide layers 132N-132P, the unreacted portions of nWFM layer 1432 on sidewalls of contact openings 720N-720P can be removed by a wet etching process,, as shown in FIGS. 15B and 15D.

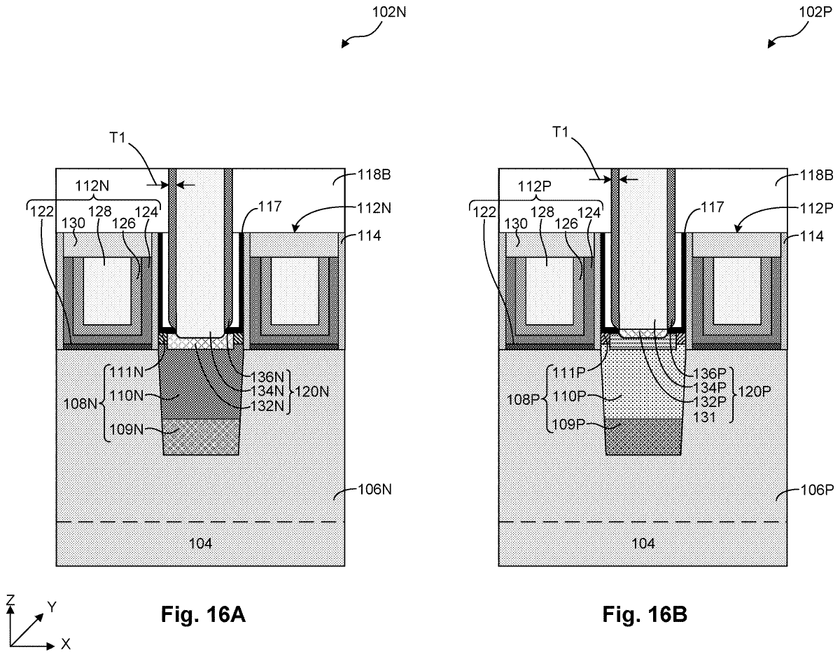

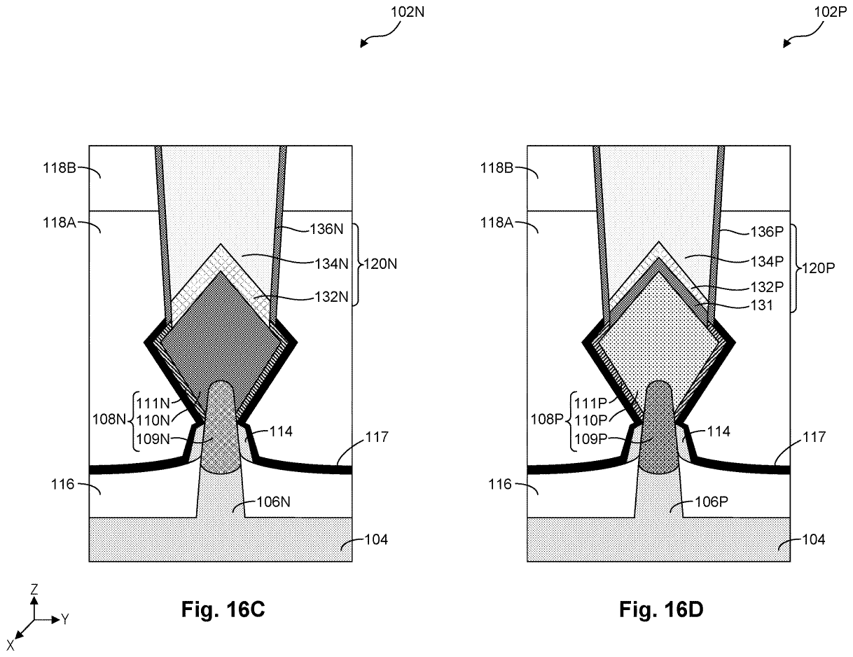

Referring to FIG. 3, in operation 345, contact plugs are formed within the first and second contact openings. For example, as shown FIGS. 16A-16D, contact plugs 134N-134P are formed within contact openings 720N-720P. The formation of contact plugs 134N-134P can include filling contact openings 720N-720P in the structures of FIGS. 15A-15D with a conductive material and performing a CMP process to form the structures of FIGS. 16A-16D. The CMP process can substantially coplanarize top surfaces of contact structures 120N-120P with the top surface of ILD layer 118B.

The present disclosure provides example semiconductor devices with FETs (e.g., finFETs 102N-102P or GAA FETs 102N-102P) having source/drain (S/D) contact structures different from each other and provides example methods of forming such FETs on the same substrate with improved barrier layers (e.g., carbon-based barrier layers 136N-136P). The example method forms arrays of n-and p-type S/D regions (e.g., S/D regions 108N-108P) on fin structures (e.g., fin structures 106N-106P) on a substrate. In some embodiments, S/D contact structures (e.g., S/D contact structures 120N-120P) on n-type S/D regions have silicide layers (e.g., silicide layer 132N) different from silicide layers (e.g., silicide layer 131) of S/D contact structures on p-type S/D regions.

In some embodiments, pWFM silicide layers (e.g., pWFM silicide layer 131) of the PFET S/D contact structures (e.g., contact structure 120P) are selectively formed on the p-type S/D regions (e.g., S/D region 108P). In contrast, nWFM silicide layers (e.g., nWFM silicide layer 132N) of the NFET S/D contact structures (e.g., contact structure 120N) are formed on the n-type S/D regions (e.g., S/D region 108N) and pWFM silicide layers. The pWFM silicide layers can be formed from a silicidation reaction between the p-type S/D regions and a pWFM layer (e.g., pWFM layer 1131) disposed on the p-type S/D regions. The nWFM silicide layers can be formed from a silicidation reaction between the n-type S/D regions and an nWFM layer (e.g., nWFM layer 1432) disposed on the n-type S/D regions and the pWFM silicide layers.

The formation of different silicide layers in NFET and PFET, instead of the formation of a single silicide layer for both NFET and PFET, increases the number of etching processes (e.g., native oxide etching processes) in the silicide layer formation process. The increased number of etching processes increases the challenges of preserving the structural and functional integrity of dielectric barrier layers in the S/D contact structures during the etching processes. The dielectric barrier layers along sidewalls of the S/D contact structures protect adjacent FET structures during the formation of S/D contact structures and provide electrical isolation between the S/D contact structures and the adjacent FET structures. Significant loss of the dielectric barrier layer material during the etching processes can damage the adjacent FET structures and/or induce shorting between the S/D contact structures and the adjacent FET structures.

In some embodiments, the dielectric barrier layers (e.g., carbide barrier layers 136N-136P) can include carbon-based materials (e.g., carbides or oxycarbides) with a carbide-to-oxide etch selectivity ranging from about 40 to about 100 or greater than about 100, a density greater than about 2 gm/cm³, and a dielectric constant less than about 5. In some embodiments, the carbide barrier layers include only Si—C bonds or only a combination of Si—C and Si—O bonds with a larger number of Si—C bonds than Si—O bonds. The Si—C bonds can provide the carbide barrier layers with a greater chemical stability, thermal stability, resistance to etching, resistance to oxygen diffusion, and etch selectivity over oxide compared to nitride barrier layers (e.g., SiN barrier layers). Also, compared to nitride barrier layers, carbide barrier layers have a lower dielectric constant, a higher etch selectivity over oxide, a higher density and a higher breakdown voltage.

The high density and high carbide-to-oxide etch selectivity can prevent or minimize etching of the carbide barrier layers during the native oxide etching in the silicide layer formation process. In some embodiments, during the native oxide etching processes, a total thickness of about 0.1 nm to about 1 nm of the carbide barrier layers can be etched, which is about 5 to about 10 times less than the total thickness of nitride barrier layers etched during the native oxide etching processes. As a result, carbide barrier layers with smaller thicknesses (e.g., about 2 to about 5 times smaller) than nitride barrier layers can be formed to adequately protect adjacent FET structures during the etching processes and provide electrical isolation between the S/D contact structures and the adjacent FET structures. Also, due to lower dielectric constant of carbide barrier layers compared to that of nitride barrier layers, thinner carbide barrier layers can be used compared to nitride barrier layers without increasing the FET parasitic capacitances. Thus, with the use of carbide barrier layers in S/D contact structures, device dimensions and manufacturing cost can be reduced without compromising device performance.

In some embodiments, a method includes forming first and second fin structures on a substrate, forming n-and p-type source/drain (S/D) regions on the first and second fin structures, respectively, forming first and second contact openings on the n-and p-type S/D regions, respectively, forming a carbon-based layer in the first and second contact openings, performing a remote plasma treatment with radicals on the carbon-based layer to form a remote plasma treated layer, selectively removing a portion of the remote plasma treated layer, forming a p-type work function metal (pWFM) silicide layer on the p-type S/D region, and forming an n-type work function metal (nWFM) silicide layer on the pWFM silicide layer and on the n-type S/D region.

In some embodiments, a method includes forming first and second fin structures on a substrate, forming n-and p-type source/drain (S/D) regions on the first and second fin structures, respectively, forming first and second contact openings on the n-and p-type S/D regions, respectively, depositing a first carbon-based layer in the first and second contact openings, performing a first remote plasma treatment on the first carbon-based layer to form a first remote plasma treated layer, depositing a second carbon-based layer on the first remote plasma treated layer, performing a second remote plasma treatment on the second carbon-based layer form a second remote plasma treated layer, selectively removing portions of the first and second remote plasma treated layers, and forming a contact plug in the first and second contact openings.

In some embodiments, as semiconductor device includes a substrate, a fin structure disposed on the substrate, a gate structure disposed on the fin structures, a source/drain (S/D) region disposed adjacent to the gate structure on the fin structure, and a contact structure disposed on the S/D region. The contact structure includes a silicide layer disposed on the S/D region, a contact plug disposed on the silicide layer, and a carbide barrier layer disposed on sidewalls of the contact plug. The carbide barrier layer includes a first density of silicon-carbon (Si—C) bonds and a second density of silicon-oxygen (Si—O) bonds, the first density being greater than the second density.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
first and second fin structures disposed on the substrate;
first and second source/drain regions disposed on the first and second fin structures, respectively;
a first contact structure, disposed on the first source/drain region, comprising:
a first silicide layer disposed on the first source/drain region,
a first contact plug disposed on the first silicide layer, and
a first carbide layer disposed on sidewalls of the first contact plug; and
a second contact structure, disposed on the second source/drain region, comprising:
a second silicide layer disposed on the second source/drain region;
a third silicide layer disposed on the second silicide layer, wherein the first and third silicide layers comprise the same metal silicide, and wherein the second and third silicide layers comprise metal silicides different from each other;
a second contact plug disposed on the third silicide layer; and
a second carbide layer disposed on sidewalls of the second contact plug.

2. The semiconductor device of claim 1, wherein the first source/drain region comprises n-type dopants, and wherein the second source/drain region comprises p-type dopants.

3. The semiconductor device of claim 1, wherein the first and third silicide layers comprise n-type work function metal silicide layers.

4. The semiconductor device of claim 1, wherein the second silicide layer comprises p-type work function metal silicide layer.

5. The semiconductor device of claim 1, wherein the first and second carbide layers comprise silicon carbide layers.

6. The semiconductor device of claim 1, wherein the first and second carbide layers comprise oxygen-doped silicon carbide layers with a silicon to oxygen to carbon ratio (Si:O:C) of about 1:1:0.2 to about 1:3:1.

7. The semiconductor device of claim 1, wherein the first and second carbide layers comprise oxygen-and nitrogen-doped silicon carbide layers with a silicon to carbon to oxygen to nitrogen ratio (Si:C:O:N) of about 1:0.1:0.9:0.5 to about 1:0.8:1.6:1.

8. The semiconductor device of claim 1, further comprising an etch stop layer disposed on and in contact with a top surface of the second silicide layer and sidewalls of the third silicide layer.

9. The semiconductor device of claim 1, further comprising an etch stop layer disposed on and in contact with a bottom surface and sidewalls of the first carbide layer.

10. The semiconductor device of claim 1, wherein a bottom surface of the first contact plug extends below a bottom surface of the first carbide layer.

11. A semiconductor device, comprising:
a substrate;
a source/drain region disposed on the substrate;
a contact structure, disposed on the source/drain region, comprising:
a first silicide layer disposed on the source/drain region;
a second silicide layer disposed on the first silicide layer, wherein the first and second silicide layers comprise metal silicides different from each other;
a conductive layer disposed on the second silicide layer; and
a carbide layer disposed on sidewalls of the conductive layer, wherein a bottom surface of the carbide layer extends below a bottom surface of the conductive layer.

12. The semiconductor device of claim 11, further comprising an etch stop layer disposed on and in contact with a top surface of the first silicide layer and sidewalls of the second silicide layer.

13. The semiconductor device of claim 11, wherein the first silicide layer comprises a p-type work function metal silicide layer, and wherein the second silicide layer comprises an n-type work function metal silicide layer.

14. The semiconductor device of claim 11, wherein the carbide layers comprise a silicon carbide layer.

15. The semiconductor device of claim 11, wherein the carbide layer comprises an oxygen-doped silicon carbide layer with a silicon to oxygen to carbon ratio (Si:O:C) of about 1:1:0.2 to about 1:3:1.

16. The semiconductor device of claim 11, further comprising:
nanostructured channel regions disposed on the substrate; and
a gate structure surrounding the nanostructured channel regions.

17. A semiconductor device, comprising:
a substrate;
a fin structure disposed on the substrate;
a gate structure disposed on the fin structure;
a source/drain region disposed adjacent to the gate structure on the fin structure;
a contact structure disposed on the source/drain region, wherein the contact structure comprises:
a silicide layer disposed on the source/drain region;
a contact plug disposed on the silicide layer; and
a carbide barrier layer disposed on sidewalls of the contact plug, wherein the carbide barrier layer comprises a first density of silicon-carbon (Si—C) bonds and a second density of silicon-oxygen (Si—O) bonds.

18. The semiconductor device of claim 17, wherein the carbide barrier layer comprises a silicon concentration of about 25 atomic % to about 35 atomic %, a carbon concentration of about 10 atomic % to about 40 atomic %, and an oxygen concentration ranging of 30 atomic % to about 55 atomic %.

19. The semiconductor device of claim 17, wherein the carbide barrier layer comprises a silicon to oxygen to carbon ratio (Si:O:C) of about 1:1:0.2 to about 1:3:1.

20. The semiconductor device of claim 17, wherein the carbide barrier layer comprises a density of about 1.7 gm/cm³ to about 2.5 gm/cm³.
